(19) United States
(12) Patent Application Publication
(10) Pub. No.: US 2025/0185421 A1
(43) Pub. Date: Jun. 5, 2025

(54) SEMICONDUCTOR LIGHT-EMITTING ELEMENT AND DISPLAY DEVICE

(71) Applicant: LG ELECTRONICS INC., Seoul (KR)

(72) Inventors: Hyunggu KIM, Seoul (KR); Sukkoo JUNG, Seoul (KR)

(73) Assignee: LG ELECTRONICS INC., Seoul (KR)

(21) Appl. No.: 18/843,998

(22) PCT Filed: Mar. 17, 2022
(86) PCT No.: PCT/KR2022/003705

§ 371 Date: Sep. 4, 2024

(51) Int. Cl. H10H 20/821; H01L 25/075; H10H 29/49

(52) U.S. Cl. CPC H10H 20/821; H01L 25/0753; H10H 29/49

(57) ABSTRACT

A semiconductor light-emitting element includes a first semiconductor region having a first shape, a second semiconductor region having a second shape different from the first shape on the first semiconductor region, and at least one or more second recess along an outer peripheral surface of the second semiconductor region. The second recess is a texture having a bottom surface, an inner surface, and a top surface.

### TECHNICAL FIELD

The embodiment relates to a semiconductor light-emitting element and a display device.

### Background Art

A large-area display includes a liquid crystal display (LCD), an OLED display, and a micro-LED display.

A micro-LED display is a display that uses a micro-LED, which is a semiconductor light-emitting element with a diameter or cross-sectional area of 100 μm or less, as a display element.

Since a micro-LED display uses a micro-LED, which is a semiconductor light-emitting element, as a display element, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since a large micro-LED display requires millions or more micro-LEDs, there is a technical problem in quickly and accurately transferring micro-LEDs to a display panel.

Recently developed transfer technologies include a pick and place process, a laser lift-off method, or a self-assembly method.

Among these, the self-assembly method is a method in which semiconductor light-emitting elements find their assembly positions in a fluid on their own, which is advantageous for implementing a large-screen display device.

On the other hand, since the micro-LED provided in the micro-LED display has a diameter or cross-sectional area of 100 μm or less, their size is very small, resulting in low luminance. When luminance is low, the contrast ratio is low, which results in poor image quality.

The decrease in luminance is closely related to the decrease in light efficiency. Therefore, a method to improve light efficiency is urgently needed to improve luminance. In particular, the micro-LEDs equipped in the micro-LED display use different semiconductor materials to emit different color light, but there is a problem that the light efficiency is reduced due to the unique characteristics of some semiconductor materials.

### DISCLOSURE

### Technical Problem

An object of the embodiment is to solve the foregoing and other problems.

Another object of the embodiment is to provide a semiconductor light-emitting element having a new structure.

In addition, another object of the embodiment is to provide a semiconductor light-emitting element capable of improving light efficiency.

In addition, another object of the embodiment is to provide a display device with easy electrical connection.

In addition, another object of the embodiment is to provide a display device capable of improving the assembly rate.

The technical problems of the embodiments are not limited to those described in this item and include those that can be understood through the description of the invention.

### Technical Solution

According to one aspect of the embodiment, in order to achieve the above or other objects, a semiconductor light-emitting element, comprises: a first semiconductor region having a first shape: a second semiconductor region having a second shape different from the first shape on the first semiconductor region; and at least one or more second recess along an outer peripheral surface of the second semiconductor region; wherein the second recess is a texture having a bottom surface, an inner surface, and a top surface.

The first shape may have a circular shape, and the second shape may have a rectangular shape.

The second semiconductor region may have a first side portion, a second side portion, a third side portion facing the first side portion, and a fourth side portion facing the second side portion, and a distance between the first side portion and the third side portion may be smaller than a diameter of the circular shape, and a distance between the second side portion and the fourth side portion may be smaller than a diameter of the circular shape.

The second recess may comprise a second-first recess having a first angle on the first side portion: a second-second recess having a second angle on the second side portion: a second-third recess having a third angle on the third side portion; and a second-fourth recess having a fourth angle on the fourth side portion; and the first angle, the second angle, the third angle, and the fourth angle may be angles of the inner side surface with respect to the bottom surface, respectively.

The first angle and the third angle may be the same, and the second angle and the fourth angle may be the same.

The first angle and the third angle may be each an acute angle, and the second angle and the fourth angle may be each an obtuse angle.

The first angle, the second angle, the third angle, and the fourth angle may be the same.

At least one or more first recess may be included along an outer peripheral surface of the first semiconductor region.

The angle of the first recess may be variable along the outer peripheral surface, and the angle may be an angle of the inner side surface with respect to the bottom surface.

The first semiconductor region may comprise a plurality of first semiconductor layers; and the second semiconductor region may comprise an active layer on the plurality of first semiconductor layers; and a plurality of second semiconductor layers on the active layer.

The plurality of first semiconductor layers may comprise a first-first semiconductor layer comprising a first dopant: a first-second semiconductor layer comprising the first dopant on the first-first semiconductor layer; and a first-third semiconductor layer on the first-second semiconductor layer; and the first recess may be disposed along an outer peripheral surface of the first-second semiconductor layer, and a side portion of the first-second semiconductor layer may be closer to a center of the first semiconductor region than a side portion of the first-first semiconductor layer and a side portion of the first-third semiconductor layer.

The plurality of second semiconductor layers may comprise a second-first semiconductor layer: a second-second semiconductor layer comprising a second dopant on the second-first semiconductor layer; and a second-third semiconductor layer comprising the second dopant on the second-second semiconductor layer, and the second recess may be disposed along an outer peripheral surface of the second-second semiconductor layer, and a side portion of the second-second semiconductor layer may be closer to a center of the second semiconductor region than a side portion of the second-first semiconductor layer and a side portion of the second-third semiconductor layer.

According to another aspect of the embodiment, a display device, comprises: a substrate comprising a plurality of sub-pixels: a plurality of first assembling wirings in the plurality of sub-pixels, respectively: a plurality of second assembling wirings in the plurality of sub-pixels, respectively: a partition wall having a plurality of assembly holes in the plurality of sub-pixels, respectively: a plurality of semiconductor light-emitting elements in the plurality of assembly holes, respectively; and a connection electrode surrounding a side portion of each of the plurality of semiconductor light-emitting elements: an electrode wiring on an upper side of each of the plurality of semiconductor light-emitting elements, wherein each of the plurality of semiconductor light-emitting elements comprises: a first semiconductor region having a first shape: a second semiconductor region having a second shape different from the first shape on the first semiconductor region; and at least one or more second recess along an outer peripheral surface of the second semiconductor region, and wherein the second recess may be a texture having a bottom surface, an inner surface, and a top surface.

The connection electrode may connect at least one of the first assembling wiring or the second assembling wiring to a side portion of the first semiconductor region.

At least one first recess may be included along an outer surface of the first semiconductor region, and the connecting electrode may be disposed in the at least one first recess.

### Advantageous Effects

According to an embodiment, as shown in FIGS. 7 and 8, at least one or more recess 159 may be disposed on a side portion of at least one or more semiconductor layer 153-2 among a plurality of second semiconductor layers 153-1, 153-2, and 153-3 disposed on the upper side of a circular semiconductor light-emitting element 150, that is, above the active layer 152, so that the light efficiency can be improved. In particular, in the case of a red light semiconductor light-emitting element, there is a problem of low luminance. In this case, since the red light semiconductor light-emitting element is provided with the recess 159 of the embodiment, the light efficiency can be improved and the luminance can be increased, so that the image quality can be improved.

According to the embodiment, as shown in FIGS. 12 to 20B, the semiconductor light-emitting elements 150A and 150B can comprise a first semiconductor region 150-11 and a second semiconductor region 150-21 thereon. The first semiconductor region 150-11 can have a circular shape, and the second semiconductor region 150-21 can have a rectangular shape. In this case, at least one or more recess 159 can be disposed along the outer peripheral surface of the second semiconductor region 150-21. That is, the recess 159 can be configured by being connected to each other by the second-first recess 159-1, the second-second recess 159-2, the second-third recess 159-3, and the second-fourth recess 159-4 provided in the first side portion 1501, the second side portion 1502, the third side portion 1503, and the fourth side portion 1504 of the second semiconductor region 150-21, respectively.

Therefore, since the second semiconductor region 150-21 has a rectangular shape, and at least one or more recess 159 is disposed along the perimeter of the second semiconductor region 150-21, the light efficiency can be further improved. In addition, since the first semiconductor region 150-11 has a circular shape, the semiconductor light-emitting element 150A having a circular shape is assembled into a circular assembly hole when implementing the display, so that the assembly rate can be improved.

According to the embodiment, as illustrated in FIGS. 21a to 22, at least one or more first recess 158 and at least one or more second recess 159 may be disposed in the first semiconductor region 150-11 and the second semiconductor region 150-21, respectively, of the semiconductor light-emitting element 150C, so that light generated in the active layer 152 can be reflected or diffused by not only the first recess 158 but also the second recess 159, thereby significantly improving light efficiency.

In particular, as illustrated in FIGS. 23 and 24, after the semiconductor light-emitting element 150C is disposed in the assembly hole 340H of the substrate 310, the connection electrode 370 may be disposed along the perimeter of the semiconductor light-emitting element 150C within the assembly hole 340H. In this case, since the connection electrode 370 is also formed within the first recess 158, the bonding force between the connection electrode 370 and the semiconductor light-emitting element 150C may be strengthened, thereby improving the fixing property of the semiconductor light-emitting element 150C, and thus improving product reliability.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to an embodiment is disposed.

FIG. 2 is a block diagram schematically showing a display device according to an embodiment.

FIG. 3 is a circuit diagram showing an example of a pixel of FIG. 2.

FIG. 4 is an enlarged view of the first panel area in the display device of FIG. 1.

FIG. 5 is an enlarged view of the A2 area of FIG. 4.

FIG. 6 is a drawing showing an example in which a light-emitting element according to an embodiment is assembled on a substrate by a self-assembly method.

FIG. 7 is a perspective view showing a semiconductor light-emitting element according to a first embodiment.

FIG. 8 is a cross-sectional view of the semiconductor light-emitting element according to the first embodiment of FIG. 7 taken along the C1-C2 line.

FIG. 9 shows a plurality of semiconductor light-emitting elements manufactured on a growth substrate according to the first embodiment.

FIG. 10 shows a change in the angle of the second recess 159 of the semiconductor light-emitting element according to the crystal orientation of the growth substrate shown in FIG. 9.

FIG. 11 shows the light efficiency according to the current in each of the comparative example and the first embodiment.

FIG. 12a is a perspective view illustrating a semiconductor light-emitting element according to a second embodiment.

FIG. 12b is a plan view illustrating a semiconductor light-emitting element according to the second embodiment.

FIG. 13 is a cross-sectional view of the semiconductor light-emitting element according to the second embodiment of FIG. 12b taken along line D1-D2.

FIG. 14 illustrates a semiconductor light-emitting element according to the second embodiment manufactured in multiple units on a growth substrate.

FIG. 15 illustrates a relationship between the crystal orientation of the growth substrate and the position of the second semiconductor region of the semiconductor light-emitting element according to the second embodiment.

FIG. 16a is a cross-sectional view taken along a crystal orientation of the growth substrate between 0° and 180°.

FIG. 16b is a cross-sectional view taken along a crystal orientation of the growth substrate between 90° and 270°.

FIGS. 17A to 17F illustrate a method for manufacturing a semiconductor light-emitting element according to the second embodiment.

FIG. 18 illustrates a relationship between the crystal orientation of a growth substrate and the position of a second semiconductor region of a semiconductor light-emitting element according to a third embodiment.

FIG. 19 illustrates a relationship between the crystal orientation of a growth substrate and the position of a second semiconductor region of a semiconductor light-emitting element according to the third embodiment.

FIG. 20A is a cross-sectional view taken along a crystal orientation of a growth substrate between 0° and 180°.

FIG. 20B is a cross-sectional view taken along a crystal orientation of a growth substrate between 90° and 270°.

FIG. 21a is a perspective view illustrating a semiconductor light-emitting element according to a fourth embodiment.

FIG. 21b is a plan view illustrating a semiconductor light-emitting element according to the fourth embodiment.

FIG. 22 is a cross-sectional view of a semiconductor light-emitting element according to the fourth embodiment of FIG. 21b, cut along the E1-E2 line.

FIG. 23 is a plan view illustrating a display device according to an embodiment.

FIG. 24 is a cross-sectional view cut along the C1-C2 line of FIG. 23.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification may comprise a TV, a signage, a mobile phone, a smart phone, a head-up display (HUD) for an automotive, a backlight unit for a laptop computer, a display for VR or AR, etc. However, the configuration according to the embodiment described in this specification may be applied to a device capable of displaying, even if it is a new product type developed in the future.

The following describes a light-emitting element according to an embodiment and a display device comprising the same.

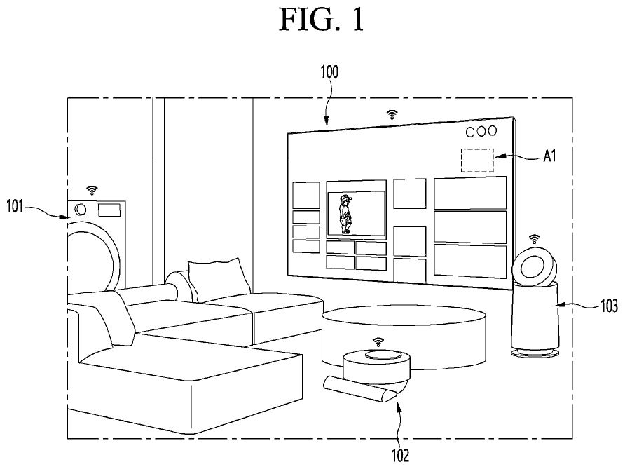

FIG. 1 illustrates a living room of a house in which a display device according to an embodiment is disposed.

Referring to FIG. 1, the display device 100 according to the embodiment can display the status of various electronic products such as a washing machine 101, a robot vacuum cleaner 102, and an air purifier 103, and can communicate with each electronic product based on IoT and control each electronic product based on user setting data.

The display device 100 according to the embodiment can comprise a flexible display manufactured on a thin and flexible substrate. The flexible display can be bent or rolled like paper while maintaining the characteristics of an existing flat panel display.

In the flexible display, visual information can be implemented by independently controlling the light emission of unit pixels disposed in a matrix form. A unit pixel means a minimum unit for implementing one color. The unit pixel of the flexible display can be implemented by a light-emitting element. In the embodiment, the light-emitting element may be a micro-LED or a nano-LED, but is not limited thereto.

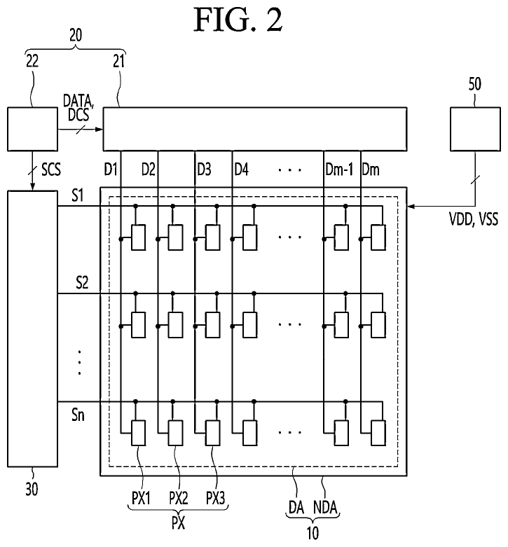

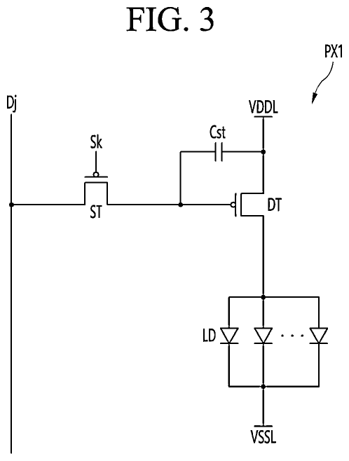

FIG. 2 is a block diagram schematically showing a display device according to an embodiment, and FIG. 3 is a circuit diagram showing an example of a pixel of FIG. 2.

Referring to FIGS. 2 and 3, the display device according to the embodiment may comprise a display panel 10, a driving circuit 20, a scan driving unit 30, and a power supply circuit 50.

The display device 100 of the embodiment may drive the light-emitting element in an active matrix (AM) method or a passive matrix (PM) method.

The driving circuit 20 may comprise a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 can be divided into a display area DA and a non-display area NDA disposed around the display area DA. The display area DA is an area where pixels PX are formed to display an image. The display panel 10 can comprise data lines (D1 to Dm, m is an integer greater than or equal to 2), scan lines (S1 to Sn, n is an integer greater than or equal to 2) crossing the data lines D1 to Dm, a high-potential voltage line VDDL to which a high-potential voltage is supplied, a low-potential voltage line VSSL to which a low-potential voltage is supplied, and pixels PX connected to the data lines D1 to Dm and the scan lines S1 to Sn.

Each of the pixels PX can comprise a first sub-pixel PX1, a second sub-pixel PX2, and a third sub-pixel PX3. The first sub-pixel PX1 can emit a first color light of a first main wavelength, the second sub-pixel PX2 can emit a second color light of a second main wavelength, and the third sub-pixel PX3 can emit a third color light of a third main wavelength. The first color light can be red light, the second color light can be green light, and the third color light can be blue light, but is not limited thereto. In addition, FIG. 2 exemplifies that each of the pixels PX comprises three sub-pixels, but is not limited thereto. That is, each of the pixels PX can comprise four or more sub-pixels.

Each of the first sub-pixel PX1, the second sub-pixel PX2, and the third sub-pixel PX3 can be connected to at least one of the data lines D1 to Dm, at least one of the scan lines S1 to Sn, and a high-potential voltage line VDDL. The first sub-pixel PX1 may comprise light-emitting elements LD and a plurality of transistors for supplying current to the light-emitting elements LD and at least one capacitor Cst, as shown in FIG. 3.

Although not shown in the drawing, each of the first sub-pixel PX1, the second sub-pixel PX2, and the third sub-pixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode and the second electrode may be a cathode electrode, but are not limited thereto.

The light-emitting element LD may be one of a lateral-type light-emitting element, a flip-chip light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as shown in FIG. 3. The driving transistor DT may comprise a gate electrode connected to a source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed of a thin film transistor. In addition, in FIG. 3, the driving transistor DT and the scan transistor ST are described mainly as being formed as P-type MOSFETs (metal oxide semiconductor field effect transistors), but the present invention is not limited thereto. The driving transistor DT and the scan transistor ST may also be formed as N-type MOSFETs. In this case, the positions of the source electrodes and the drain electrodes of each of the driving transistor DT and the scan transistor STs may be changed.

In addition, in FIG. 3, the first sub-pixel PX1, the second sub-pixel PX2, and the third sub-pixel PX3 are illustrated as comprising 2TIC (2 Transistor-1 capacitor) having one driving transistor DT, one scan transistor ST, and one capacitor Cst, but the present invention is not limited thereto. The first sub-pixel PX1, the second sub-pixel PX2, and the third sub-pixel PX3 may each comprise a plurality of scan transistors STs and a plurality of capacitors Csts.

The second sub-pixel PX2 and the third sub-pixel PX3 can be expressed by substantially the same circuit diagram as the first sub-pixel PX1, so that a detailed description thereof is omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts digital video data DATA into analog data voltages according to the source control signal DCS and supplies the converted data to data lines D1 to Dm of the display panel 10.

The timing control unit 22 receives digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driver 21 and the scan driver 30. The control signals may comprise a source control signal DCS for controlling the operation timing of the data driver 21 and a scan control signal SCS for controlling the operation timing of the scan driver 30.

The driving circuit 20 may be disposed in a non-display area NDA provided on one side of the display panel 10. The driving circuit 20 may be formed as an integrated circuit (IC) and mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not shown) other than the display panel 10.

The data driving unit 21 may be mounted on the display panel 10 in a chip on glass (COG) manner, a chip on plastic (COP) manner, or an ultrasonic bonding manner, and the timing control unit 22 may be mounted on the circuit board.

The scan driving unit 30 receives a scan control signal SCS from the timing control unit 22. The scan driving unit 30 generates scan signals according to the scan control signal SCS and supplies the scan signals to the scan lines S1 to Sn of the display panel 10. The scan driving unit 30 may comprise a plurality of transistors and may be formed in a non-display area NDA of the display panel 10. Alternatively, the scan driver 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film, such as a flexible printed circuit board, a printed circuit board, or a chip on film. The circuit board may be bent to the lower part of the display panel 10. As a result, one side of the circuit board may be attached to one edge of the display panel 10, and the other side may be disposed on the lower part of the display panel 10 and connected to a system board on which a host system is mounted.

The power supply circuit 50 can generate voltages required for driving the display panel 10 from the main power applied from the system board and supply the voltages to the display panel 10. For example, the power supply circuit 50 can generate a high-potential voltage VDD and a low-potential voltage VSS for driving the light-emitting elements LD of the display panel 10 from the main power and supply the high-potential voltage VDD and the low-potential voltage VSS to the high-potential voltage line VDDL and the low-potential voltage line VSSL of the display panel 10. In addition, the power supply circuit 50 can generate and supply driving voltages for driving the driving circuit 20 and the scan driving unit 30 from the main power.

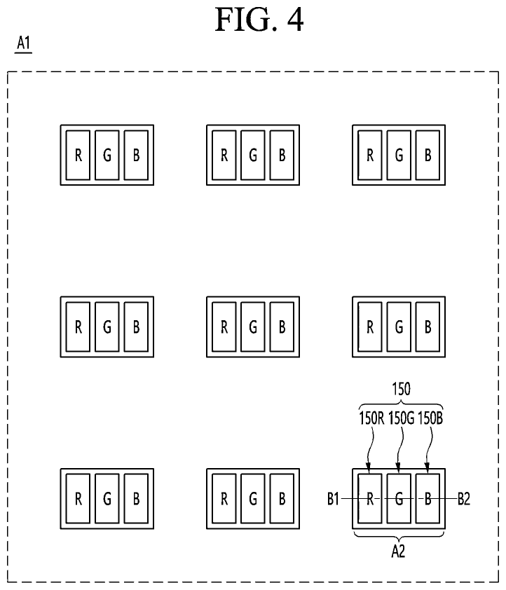

FIG. 4 is an enlarged view of the first panel area in the display device of FIG. 3.

Referring to FIG. 4, the display device 100 of the embodiment can be manufactured by mechanically and electrically connecting a plurality of panel areas such as the first panel area A1 by tiling.

The first panel area A1 may comprise a plurality of semiconductor light-emitting elements 150 disposed for each unit pixel (PX of FIG. 2).

For example, the unit pixel PX may comprise a first sub-pixel PX1, a second sub-pixel PX2, and a third sub-pixel PX3. For example, a plurality of red semiconductor light-emitting elements 150R may be disposed in the first sub-pixel PX1, a plurality of green semiconductor light-emitting elements 150G may be disposed in the second sub-pixel PX2, and a plurality of blue semiconductor light-emitting elements 150B may be disposed in the third sub-pixel PX3. The unit pixel PX may further comprise a fourth sub-pixel in which no semiconductor light-emitting elements are disposed, but is not limited thereto.

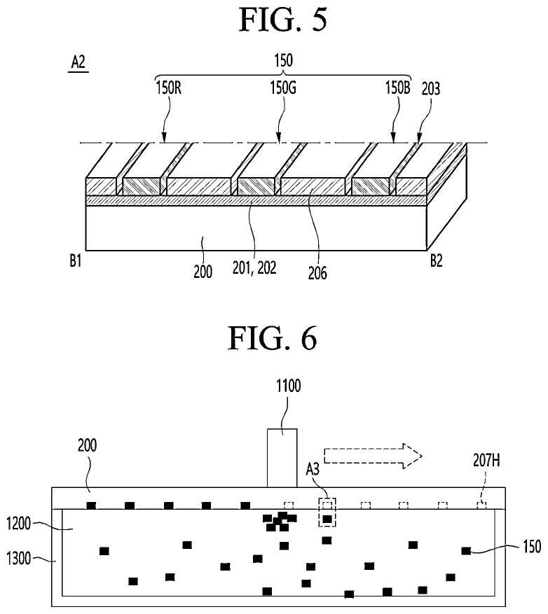

FIG. 5 is an enlarged view of the A2 area of FIG. 4.

Referring to FIG. 5, the display device 100 of the embodiment may comprise a substrate 200, assembling wiring 201 and 202, an insulating layer 206, and a plurality of semiconductor light-emitting elements 150. More components may be included than these.

The assembling wiring may comprise a first assembling wiring 201 and a second assembling wiring 202 that are spaced apart from each other. The first assembling wiring 201 and the second assembling wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited to, a red semiconductor light-emitting element 150, a green semiconductor light-emitting element 150G, and a blue semiconductor light-emitting element 150B to form a unit pixel (sub-pixel), and may also comprise a red phosphor and a green phosphor to implement red and green, respectively.

The substrate 200 may be a support member that supports components disposed on the substrate 200, or a protective member that protects the components.

The substrate 200 may be a rigid substrate or a flexible substrate. The substrate 200 may be formed of sapphire, glass, silicon, or polyimide. In addition, the substrate 200 may comprise a flexible material such as a polyethylene naphthalate (PEN), a polyethylene terephthalate (PET). In addition, the substrate 200 may be a transparent material, but is not limited thereto. The substrate 200 can function as a support substrate in the display panel, and can also function as an assembly substrate when self-assembling the light-emitting element.

The substrate 200 can be a backplane equipped with circuits in the sub-pixels PX1, PX2, and PX3 shown in FIGS. 2 and 3, such as transistors ST and DT, capacitors Cst, and signal wiring, but is not limited thereto.

The insulating layer 206 may comprise an insulating and flexible organic material such as polyimide, PAC, PEN, PET, polymer, etc., or an inorganic material such as silicon oxide (SiO₂) or silicon nitride series (SiNₓ), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, but electrically insulating in a direction horizontal to the thickness.

The insulating layer 206 may comprise an assembly hole 203 into which a semiconductor light-emitting element 150 is inserted. Therefore, during self-assembly, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element have different shapes, respectively, and an assembly hole 203 having a shape corresponding to each shape of these semiconductor light-emitting elements may be provided. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a second major axis, and the blue semiconductor light-emitting element may have a second oval shape having a second minor axis and a second major axis, but are not limited thereto. The second major axis of the oval shape of the blue semiconductor light-emitting element may be greater than the second major axis of the oval shape of the green semiconductor light-emitting element, and the second minor axis of the oval shape of the blue semiconductor light-emitting element may be smaller than the first minor axis of the oval shape of the green semiconductor light-emitting element.

Meanwhile, the method of mounting the semiconductor light-emitting element 150 on the substrate 200 may comprise, for example, a self-assembly method (FIG. 6) and a transfer method.

FIG. 6 is a drawing showing an example in which a light-emitting element according to an embodiment is assembled on a substrate by a self-assembly method.

Based on FIG. 6, an example in which a semiconductor light-emitting element according to an embodiment is assembled on a display panel by a self-assembly method using an electromagnetic field will be described.

The assembly substrate 200 described below can also function as a panel substrate 200a in a display device after assembling the light-emitting element, but the embodiment is not limited thereto.

Referring to FIG. 6, the semiconductor light-emitting element 150 can be put into a chamber 1300 filled with a fluid 1200, and the semiconductor light-emitting element 150 can be moved to the assembly substrate 200 by a magnetic field generated from the assembly device 1100. At this time, the light-emitting element 150 adjacent to the assembly hole 207H of the assembly substrate 200 can be assembled into the assembly hole 207H by the DEP force caused by the electric field of the assembling wirings. The fluid 1200 can be water such as ultrapure water, but is not limited thereto. The chamber can be called a tank, a container, a vessel, etc.

After the semiconductor light-emitting element 150 is put into the chamber 1300, the assembly substrate 200 can be disposed on the chamber 1300. According to an embodiment, the assembly substrate 200 may be put into the chamber 1300.

After the assembly substrate 200 is disposed in the chamber, an assembly device 1100 that applies a magnetic field may move along the assembly substrate 200. The assembly device 1100 may be a permanent magnet or an electromagnet.

The assembly device 1100 may move in contact with the assembly substrate 200 to maximize the area affected by the magnetic field within the fluid 1200. According to an embodiment, the assembly device 1100 may comprise a plurality of magnetic bodies or may comprise a magnetic body of a size corresponding to the assembly substrate 200. In this case, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

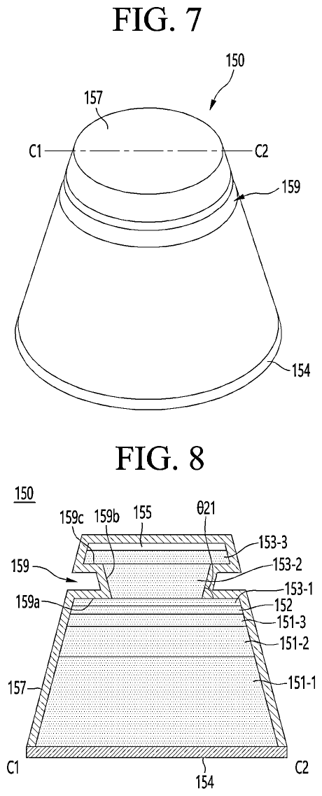

Hereinafter, various embodiments for solving the above-described problem will be described with reference to FIGS. 7 to 24. Any description omitted below can be easily understood from the descriptions given above with respect to FIGS. 1 to 6 and the corresponding drawings.

### First Embodiment

FIG. 7 is a perspective view illustrating a semiconductor light-emitting element according to a first embodiment. FIG. 8 is a cross-sectional view of the semiconductor light-emitting element according to the first embodiment of FIG. 7 taken along the line C1-C2.

Referring to FIGS. 7 and 8, the semiconductor light-emitting element 150 according to the first embodiment may comprise a plurality of first semiconductor layers 151-1, 151-2, and 151-3, an active layer 152, a plurality of second semiconductor layers 153-1, 153-2, and 153-3, and at least one or more recess 159.

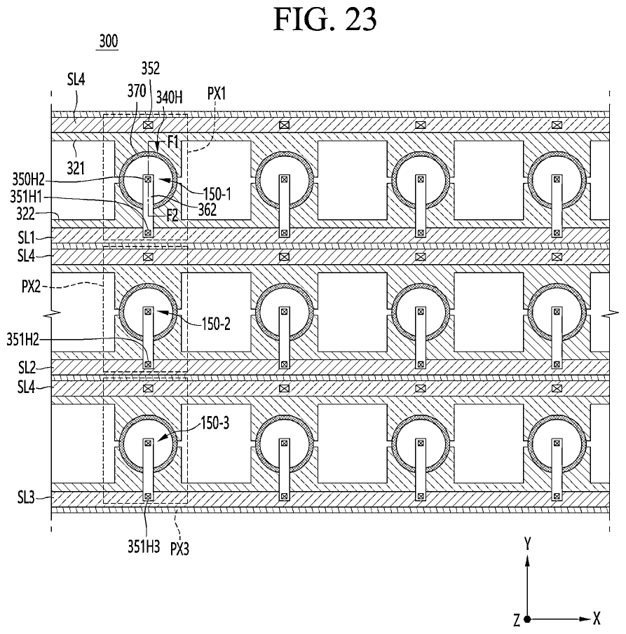

The semiconductor light-emitting element 150 according to the first embodiment may be a first semiconductor light-emitting element 150-1, a second semiconductor light-emitting element 150-2, and/or a third semiconductor light-emitting element 150-3 illustrated in FIG. 23. The semiconductor light-emitting element 150 according to the first embodiment is made of a group III-V compound semiconductor material or a group II-VI compound semiconductor material, and can generate light corresponding to a unique wavelength of the compound semiconductor material. Typically, when the compound semiconductor material is of the GaP series, red light is generated, and when it is of the GaN series, green light or blue light may be generated, but is not limited thereto.

Although the side portions of the plurality of first semiconductor layers 151-1, 151-2, and 151-3 are illustrated as having inclined surfaces in the drawing, they may be perpendicular to the ground. Although the side portions of the plurality of second semiconductor layers 153-1, 153-2, and 153-3 are illustrated as having inclined surfaces in the drawing, they may be perpendicular to the ground. The inclined surfaces of the plurality of first semiconductor layers 151-1, 151-2, and 151-3 and the inclined surfaces of the plurality of second semiconductor layers 153-1, 153-2, and 153-3 may have the same inclination angles with respect to the ground, but are not limited thereto.

The plurality of first semiconductor layers 151-1, 151-2, and 151-3 and the plurality of second semiconductor layers 153-1, 153-2, and 153-3 may each have a circular shape. That is, the semiconductor light-emitting element 150 according to the first embodiment may have a circular shape.

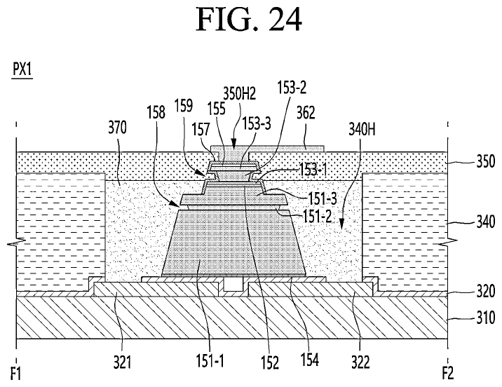

As will be described later, the semiconductor light-emitting element 150 having a circular shape can be easily assembled into the assembly hole (340H in FIG. 24) during self-assembly. For example, since the assembly hole 340H has a circular shape, when the semiconductor light-emitting element 150 has a circular shape, the semiconductor light-emitting element 150 can be easily inserted into the assembly hole 340H.

Meanwhile, the active layer 152 can be disposed on a plurality of first semiconductor layers 151-1, 151-2, and 151-3, and a plurality of second semiconductor layers 153-1, 153-2, and 153-3 can be disposed on the active layer 152. The plurality of first semiconductor layers 151-1, 151-2, and 151-3 can generate first carriers, such as electrons, and transfer the first carriers to the active layer 152, and the plurality of second semiconductor layers 153-1, 153-2, and 153-3 can generate second carriers, such as holes, and transfer the second carriers to the active layer 152. The active layer 152 can generate color light of a specific wavelength band by recombinating the electrons provided from the plurality of first semiconductor layers 151-1, 151-2, and 151-3 and the holes provided from the plurality of second semiconductor layers 153-1, 153-2, and 153-3.

The plurality of first semiconductor layers comprise a first-first semiconductor layer 151-1, a first-second semiconductor layer 151-2, and a first-third semiconductor layer 151-3, but there may be more layers than these. The plurality of second semiconductor layers comprise a second-first semiconductor layer 153-1, a second-second semiconductor layer 153-2, and a second-third semiconductor layer 153-3, but there may be more layers than these.

The semiconductor layer 151-1 and the first-second semiconductor layer 151-2 may each comprise a first dopant, and the second-second semiconductor layer 153-2 and the second-third semiconductor layer 153-3 may each comprise a second dopant. For example, the first dopant may be silicon (Si), etc., and the second dopant may be magnesium (Mg), etc.

The semiconductor layer 151-3 and the second-first semiconductor layer 153-1 may be cladding layers. That is, the first-third semiconductor layer 151-3 can prevent holes of the active layer 152 from being transferred to the first-second semiconductor layer 151-2, and the second-first semiconductor layer 153-1 can prevent electrons of the active layer 152 from being transferred to the second-second semiconductor layer 153-2. The first-third semiconductor layer 151-3 and the second-first semiconductor layer 153-1 may each be undoped semiconductor layers. That is, the first-third semiconductor layer 151-3 and the second-second semiconductor layer 153-2 may not comprise a dopant, but are not limited thereto. For example, the first-third semiconductor layer 151-3 may be in contact with a lower side of the active layer 152, and the second-first semiconductor layer 153-1 may be in contact with an upper side of the active layer 152.

As described above, when the semiconductor light-emitting element 150 is a red light semiconductor light-emitting element, the semiconductor light-emitting element 150 may be made of a GaP series compound semiconductor material.

The etch rates of the semiconductor layer 151-1, the first-second semiconductor layer 151-2, and the first-third semiconductor layer 151-3 may be different from each other. For example, the etch rate of the first-second semiconductor layer 151-2 may be faster than the etch rate of the first-first semiconductor layer 151-1. For example, the etch rate of the first-second semiconductor layer 151-2 may be faster than the etch rate of the first-third semiconductor layer 151-3. The etch rates of the second-first semiconductor layer 153-1, the second-second semiconductor layer 153-2, and the second-third semiconductor layer 153-3 may be different from each other. For example, the etch rate of the second-second semiconductor layer 153-2 may be faster than the etch rate of the second-first semiconductor layer 153-1. For example, the etch rate of the second-second semiconductor layer 153-2 may be faster than the etch rate of the second-third semiconductor layer 153-3. Here, the etching refers to wet etching using an etchant.

The semiconductor layer 151-1 and the first-third semiconductor layer 151-3 may be made of the same compound semiconductor material, and the second-first semiconductor layer 153-1 and the second-third semiconductor layer 153-3 may be made of the same compound semiconductor material. For example, the first-first semiconductor layer 151-1, the first-third semiconductor layer 151-3, the second-first semiconductor layer 153-1, and the second-third semiconductor layer 153-3 may comprise AlGalInP. For example, the first-second semiconductor layer 151-2 and the second-second semiconductor layer 153-2 may comprise AlInP.

Meanwhile, the recess 159 may have a circular ring since it is disposed along the outer peripheral surface of at least one semiconductor layer among the plurality of second semiconductor layers 153-1, 153-2, and 153-3. For example, the recess 159 can be disposed along the outer peripheral surface of the second-second semiconductor layer 153-2. As described above, since the etch rate of the second-second semiconductor layer 153-2 comprising AlInP is faster than the etch rates of each of the second-first semiconductor layer 153-1 and the second-third semiconductor layer 153-3 comprising AlGaInP, when wet etching is performed by an etchant, the outer side portion of the second-second semiconductor layer 153-2 can be etched faster than the outer side portion of each of the second-first semiconductor layer 153-1 and the second-third semiconductor layer 153-3, so that the recess 159 can be formed. That is, the side portion of the second-second semiconductor layer 153-2 can be closer to the center of the semiconductor light-emitting element 150 than the side portions of the second-first semiconductor layer 153-1 and the second-third semiconductor layer 153-3. In other words, the side portion of the second-second semiconductor layer 153-2 may be positioned further inwardly relative to the side portion of the second-first semiconductor layer 153-1 and the side portion of the second-third semiconductor layer 153-3, respectively, so that the recess 159 may be formed.

The recess 159 may be positioned above the active layer 152. Accordingly, light generated in the active layer 152 may be reflected or diffused in more diverse directions by the shape of the recess 159, so that the light efficiency may be improved.

The recess 159 may be a texture having a bottom surface 159a, an inner surface 159b, and a top surface 159c. For example, the bottom surface 159a may be the upper surface of the second-first semiconductor layer 153-1, the inner surface 159b may be the side portion of the second-second semiconductor layer 153-2, and the top surface 159c may be the lower surface of the second-third semiconductor layer 153-3. As the second-second semiconductor layer 153-2 is etched from the outer side portion to the inside by wet etching, a part of the upper surface of the second-first semiconductor layer 153-1 and a part of the lower surface of the second-third semiconductor layer 153-3 may be exposed. The exposed upper surface of the second-first semiconductor layer 153-1 and the exposed lower surface of the second-third semiconductor layer 153-3 may be the bottom surface 159a and the top surface 159c, respectively.

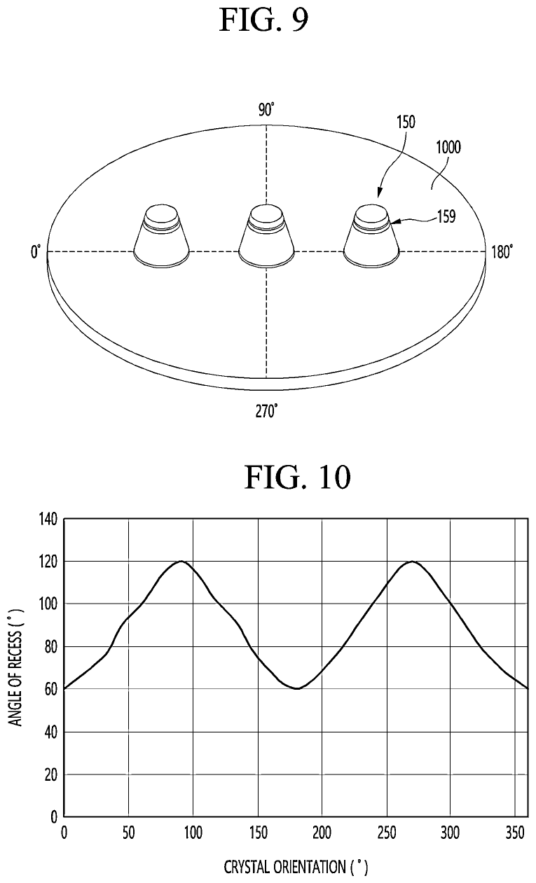

In the embodiment, the angle θ11 of the recess 159 may vary along the outer peripheral surface of the second-second semiconductor layer 153-2, as illustrated in FIG. 10. This is due to the crystal orientation of the growth substrate (1000 in FIG. 9) for manufacturing the semiconductor light-emitting element 150. The angle θ11 may be an angle of the inner surface 159b with respect to the bottom surface 159a.

As illustrated in FIG. 9, the growth substrate 1000 may have a crystal orientation from 0° to 360°. For example, when the growth substrate 1000 is made of sapphire, the crystal orientation of the sapphire may be determined from 0° to 360°. The semiconductor light-emitting element 150 may be manufactured on the growth substrate 1000 having such a crystal orientation. That is, a plurality of first semiconductor layers 151-1, 151-2, and 151-3, an active layer 152, and a plurality of second semiconductor layers 153-1, 153-2, and 153-3 can be deposited on a growth substrate 1000. When these plurality of first semiconductor layers 151-1, 151-2, and 151-3, an active layer 152, and a plurality of second semiconductor layers 153-1, 153-2, and 153-3 are deposited on the growth substrate 1000, they are grown along the crystal orientation of the growth substrate 1000, and accordingly, the crystal characteristics of each of the plurality of first semiconductor layers 151-1, 151-2, and 151-3, the active layer 152, and the plurality of second semiconductor layers 153-1, 153-2, and 153-3 can vary. Due to such different crystal characteristics, the etching characteristics in the direction corresponding to each crystal orientation of the growth substrate 1000 may also vary.

As illustrated in FIG. 10, as the crystal orientation of the growth substrate 1000 increases from 0° to 90°, the angle θ11 of the recess 159 may become increasingly larger. As the crystal orientation of the growth substrate 1000 increases from 90° to 180°, the angle θ11 of the recess 159 may become increasingly smaller. As the crystal orientation of the growth substrate 1000 increases from 180° to 270°, the angle θ11 of the recess 159 may become increasingly larger. As the crystal orientation of the growth substrate 1000 increases from 270° to 360°, the angle θ11 of the recess 159 may become increasingly smaller. Accordingly, as the crystal orientation of the growth substrate 1000 increases from 0° to 360°, the angle θ11 of the recess 159 may vary in the order of acute angle→obtuse angle→acute angle→obtuse angle→acute angle. In other words, the angle θ11 of the recess 159 may vary depending on the direction viewed from the side portion of the semiconductor light-emitting element 150. For example, the variable range of the angle θ11 may be from 60° to 120°, but is not limited thereto.

Although not illustrated, another angle of the inner surface 159b with respect to the top surface 159c may also vary as the crystal orientation of the growth substrate 1000 increases from 0° to 360°. For example, as the crystal orientation of the growth substrate 1000 increases from 0° to 360°, the corresponding angle of the recess 159, i.e., the angle of the inner side surface 159b relative to the top surface 159c, may vary in the order of obtuse angle→acute angle→obtuse angle→acute angle→obtuse angle, but is not limited thereto.

According to an embodiment, at least one or more recess 159 may be disposed on the side portion of at least one or more semiconductor layer among the plurality of second semiconductor layers 153-1, 153-2, and 153-3 disposed on the active layer 152, thereby improving the light efficiency.

In particular, in the case of a red light semiconductor light-emitting element, there is a problem of low luminance. In this case, by providing the recess 159 of the embodiment to the red light semiconductor light-emitting element, the light efficiency can be improved, thereby increasing the luminance, and thus improving the image quality.

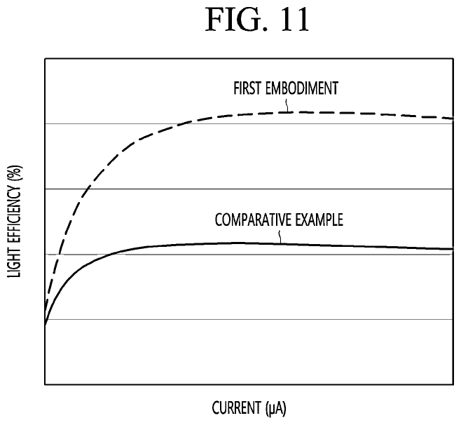

As illustrated in FIG. 11, a higher light efficiency can be obtained in an embodiment provided with a recess 159, compared to a comparative example without a recess.

Meanwhile, a semiconductor light-emitting element 150 according to the first embodiment may comprise a first electrode 154, a second electrode 155, and a passivation layer 157.

The first electrode 154 may be disposed under a plurality of first semiconductor layers 151-1, 151-2, and 151-3, and the second electrode 155 may be disposed on a plurality of second semiconductor layers 153-1, 153-2, and 153-3. The passivation layer 157 can surround the plurality of first semiconductor layers 151-1, 151-2, and 151-3, the active layer 152, and the plurality of second semiconductor layers 153-1, 153-2, and 153-3. Since the passivation has a thickness smaller than the depth of the recess 159, a groove corresponding to the recess 159 can be formed along the outer peripheral surface.

The first electrode 154 can be vertically overlapped with each of the plurality of first semiconductor layers 151-1, 151-2, and 151-3 and the passivation layer 157.

Although not illustrated, the first electrode 154 may be formed after the passivation on the side portion of at least one or more layer of the lower side of the plurality of first semiconductor layers 151-1, 151-2, and 151-3 is removed. In this case, the first electrode 154 may be in contact with the plurality of first semiconductor layers 151-1, 151-2, and 151-3 with a wider area, so that when the semiconductor light-emitting element 150 is implemented as a display, the current flow can be smoother and the luminance can be improved.

### Second Embodiment

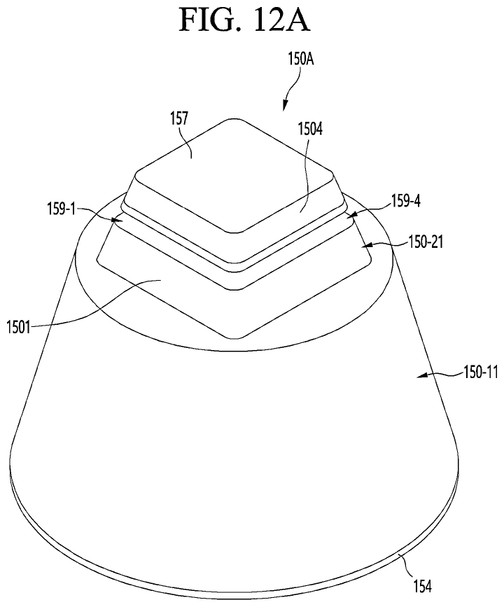

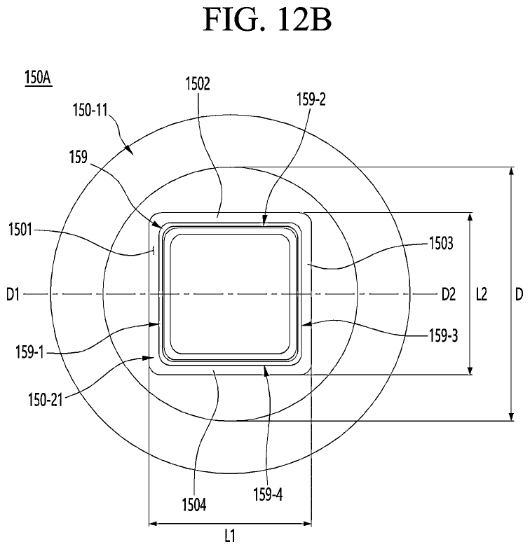

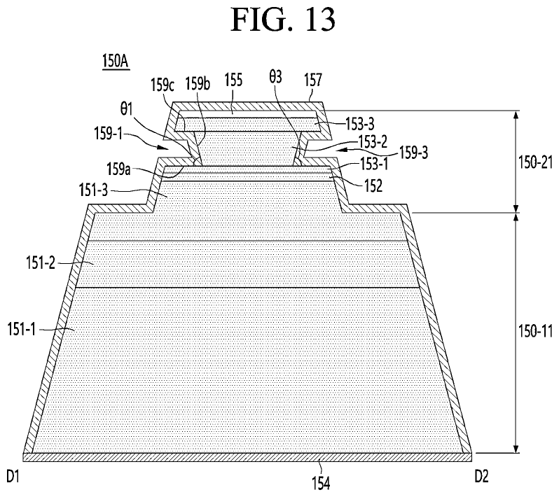

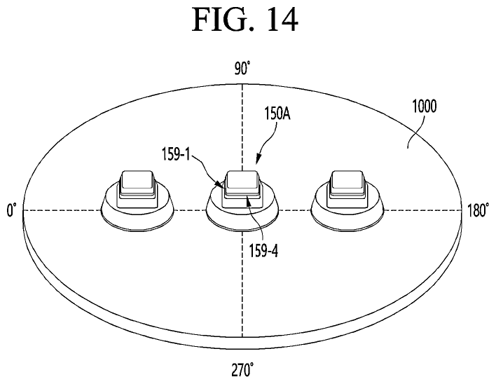

FIG. 12a is a perspective view illustrating a semiconductor light-emitting element according to a second embodiment. FIG. 12b is a plan view illustrating a semiconductor light-emitting element according to the second embodiment. FIG. 13 is a cross-sectional view of the semiconductor light-emitting element according to the second embodiment of FIG. 12b taken along the line D1-D2.

The embodiment is similar to the first embodiment except that the first semiconductor region 150-11 and the second semiconductor region 150-21 have different shapes. In the second embodiment, the same drawing reference numerals are given to components having the same structure, shape, and/or function as those of the first embodiment, and detailed descriptions are omitted.

Referring to FIGS. 12a, 12b, and 13, the semiconductor light-emitting element 150A according to the second embodiment may comprise a first semiconductor region 150-11, a second semiconductor region 150-21, and at least one or more recess 159.

The semiconductor region 150-21 may be disposed on the first semiconductor region 150-11. The first semiconductor region 150-11 and the second semiconductor region 150-21 may be formed integrally and have different shapes. When viewed from above, the first semiconductor region 150-11 may have a first shape, and the second semiconductor region 150-21 may have a second shape different from the first shape. For example, when viewed from above, the first semiconductor region 150-11 may have a circular shape, and the second semiconductor region 150-21 may have a rectangular shape. That is, the first semiconductor region 150-11 may have a circular shape along its perimeter, and the second semiconductor region 150-21 may have a rectangular shape along its perimeter.

Since the first semiconductor region 150-11 has a circular shape, the semiconductor light-emitting element 150A can be easily assembled on the substrate (310 of FIG. 24) during self-assembly. The assembly hole 340H may have a shape corresponding to the shape of the semiconductor light-emitting element 150A. When the semiconductor light-emitting element 150A and the assembly hole 340H each have a shape corresponding to each other, that is, a circular shape, the semiconductor light-emitting element 150A can be best assembled into the assembly hole 340H. In an embodiment, since the assembly hole 340H has a circular shape and the semiconductor light-emitting element 150A has a shape corresponding to the shape of the assembly hole 340H, that is, a circular shape, the semiconductor light-emitting element 150A can be easily assembled into the assembly hole 340H during self-assembly.

Meanwhile, in FIG. 23, the first semiconductor light-emitting element 150-1, the second semiconductor light-emitting element 150-2, and the third semiconductor light-emitting element 150-3 are illustrated as having the same shape, i.e., a circular shape, and the assembly holes 340H corresponding to each of the first semiconductor light-emitting element 150-1, the second semiconductor light-emitting element 150-2, and the third semiconductor light-emitting element 150-3 are also illustrated as having a circular shape. However, when the first semiconductor light-emitting element 150-1, the second semiconductor light-emitting element 150-2, and the third semiconductor light-emitting element 150-3 have the same shape and self-assembly is performed at the same time, incorrect assembly may occur in which a semiconductor light-emitting element that is not suitable for the assembly hole 340H is assembled into the assembly hole 340H. For example, as a correct assembly, a first semiconductor light-emitting element 150-1 is assembled into an assembly hole 340H of a first sub-pixel PX1, a second semiconductor light-emitting element 150-2 is assembled into an assembly hole 340H of a second sub-pixel PX2, and a third semiconductor light-emitting element 150-3 is assembled into an assembly hole 340H of a third sub-pixel PX3. However, since the assembly holes 340H of each of the first sub-pixel PX1, the second sub-pixel PX2, and the third sub-pixel PX3 have the same shape, an incorrect assembly may occur, for example, in which the first semiconductor light-emitting element 150-1 is assembled into an assembly hole 340H of the second sub-pixel PX2 or the third sub-pixel PX3, or the second semiconductor light-emitting element 150-2 is assembled into an assembly hole 340H of the first sub-pixel PX1 or the third sub-pixel PX3.

Therefore, when the first semiconductor light-emitting element 150-1, the second semiconductor light-emitting element 150-2, and the third semiconductor light-emitting element 150-3 are self-assembled at the same time, the shapes of the first sub-pixel PX1, the second sub-pixel PX2, and the third sub-pixel PX3 may be different, and the shapes of the first semiconductor light-emitting element 150-1, the second semiconductor light-emitting element 150-2, and the third semiconductor light-emitting element 150-3 may also be different. In this case, the first semiconductor region 150-11 of the embodiment may have a circular shape, a first oval shape having a first major axis, a second oval shape having a second major axis greater than the first major axis, etc. For example, the first semiconductor region 150-11 of the first semiconductor light-emitting element 150-1 may have a circular shape, the first semiconductor region 150-11 of the second semiconductor light-emitting element 150-2 may have a first oval shape, and the first semiconductor region 150-11 of the third semiconductor light-emitting element 150-3 may have a second oval shape, but are not limited thereto.

Meanwhile, the second semiconductor region 150-21 may improve light efficiency.

If, as in the first embodiment (FIGS. 7 and 8), the upper side of the semiconductor light-emitting element 150, i.e., the second semiconductor region 150-21, has a circular shape, it is difficult for light generated in the semiconductor light-emitting element 150 to be emitted forward due to a confinement effect. However, as in the second embodiment, when the second semiconductor region 150-21 has a rectangular shape, the light confinement effect may be alleviated, so that the light generated from the semiconductor light-emitting element 150A can be more easily emitted forward, thereby improving light efficiency.

The semiconductor region 150-21 may comprise a first side portion 1501, a second side portion 1502, a third side portion 1503, and a fourth side portion 1504. The first side portion 1501 and the third side portion 1503 may face each other, and the second side portion 1502 and the fourth side portion 1504 may face each other. Although the first side portion 1501, the second side portion 1502, the third side portion 1503, and the fourth side portion 1504 of the second semiconductor region 150-21 are each illustrated as having an inclined surface in the drawing, they may be perpendicular to the ground.

The distance L1 between the first side portion 1501 and the third side portion 1503 can be smaller than the diameter D of the circular shape. The distance L2 between the second side portion 1502 and the fourth side portion 1504 can be smaller than the diameter D of the circular shape. For example, each of the first side portion 1501, the second side portion 1502, the third side portion 1503, and the fourth side portion 1504 can be positioned inwardly relative to the side portion of the first semiconductor region 150-11. An upper surface of the first semiconductor region 150-11 corresponding between each of the first side portion 1501, the second side portion 1502, the third side portion 1503, and the fourth side portion 1504 and the side portion of the first semiconductor region 150-11 can be exposed. For example, the first semiconductor region 150-11 may comprise a first region that vertically overlaps the second semiconductor region 150-21 and a second region that does not vertically overlap the second semiconductor region 150-21. In this case, the upper surface of the second region may be exposed.

Each of the first side portion 1501, the second side portion 1502, the third side portion 1503, and the fourth side portion 1504 may be connected to each other along the outer peripheral surface of the second semiconductor region 150-21.

Meanwhile, at least one or more recess 159 may be disposed along the outer peripheral surface of the second semiconductor region 150-21.

The recess 159 may be disposed on each of the first side portion 1501, the second side portion 1502, the third side portion 1503, and the fourth side portion 1504. The recess 159 disposed on each of the first side portion 1501, the second side portion 1502, the third side portion 1503, and the fourth side portion 1504 may be connected to each other. The recess 159 may be textured having a bottom surface 159a, an inner surface 159b, and a top surface 159c.

The recess 159 may comprise a second-first recess 159-1 having a first angle θ1 on the first side portion 1501, a second-second recess 159-2 having a second angle θ2 on the second side portion 1502, a second-third recess 159-3 having a third angle θ3 on the third side portion 1503, and a second-fourth recess 159-4 having a fourth angle θ1 on the fourth side portion 1504. In this case, the first angle θ1 of the second-first recess 159-1, the second angle θ2 of the second-second recess 159-2, the third angle θ3 of the second-third recess 159-3, and the fourth angle θ1 of the second-fourth recess 159-4 may each be an angle of the inner surface 159b with respect to the bottom surface 159a.

The recess 159-1, the second-second recess 159-2, the second-third recess 159-3, and the second-fourth recess 159-4 may be connected to each other along the outer peripheral surface of the second semiconductor region 150-21.

Meanwhile, the first angle θ1 and the third angle θ3 may be the same. The second angle 02 and the fourth angle θ1 may be the same. The first angle θ1 and the second angle θ2 may be different. The first angle θ1 and the fourth angle θ1 may be different. The third angle θ3 and the second angle θ2 may be different. The third angle θ3 and the fourth angle θ1 may be different. For example, the first angle θ1 and the third angle θ3 may each have an acute angle, and the second angle θ2 and the fourth angle θ1 may each have an obtuse angle, but are not limited thereto.

The relationship between these angles θ1, 02, 03, and 04 will be described with reference to FIGS. 14 to 16B.

As illustrated in FIG. 14, a plurality of semiconductor light-emitting elements 150A may be manufactured on a growth substrate 1000. At this time, the growth of each of the plurality of semiconductor layers of the plurality of semiconductor light-emitting elements 150A is affected by the crystal orientation of the growth substrate 1000.

The growth substrate 1000 can have a crystal orientation from 0° to 360°. For example, when the growth substrate 1000 is made of sapphire, the crystal orientation of the sapphire can be determined from 0° to 360°.

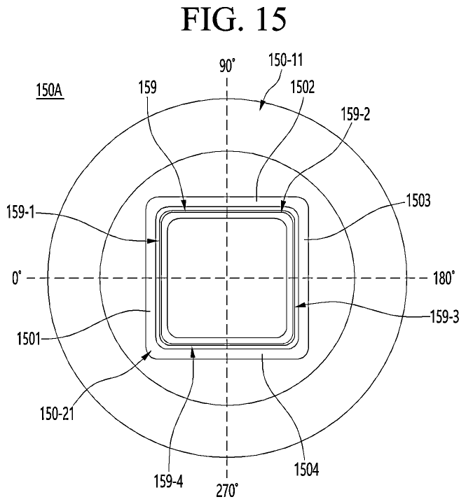

A plurality of semiconductor light-emitting elements 150A can be manufactured on a growth substrate 1000 having such a crystal orientation. That is, after a plurality of semiconductor layers are deposited on a growth substrate 1000 having a preset crystal orientation, mesa etching can be performed to manufacture a plurality of semiconductor light-emitting elements 150A, thereby forming a first semiconductor region 150-11 having a circular shape and a second semiconductor region 150-21 having a rectangular shape. For example, as illustrated in FIG. 15, a second semiconductor region 150-21 having a first side portion 1501, a second side portion 1502, a third side portion 1503, and a fourth side portion 1504 of second semiconductor layers 153-1, 153-2, and 153-3 can be formed by mesa-etching a plurality of semiconductor layers corresponding to crystal orientations of 0°, 90°, 180°, and 270°, respectively, of the growth substrate 1000. At this time, a second-first recess 159-1, a second-second recess 159-2, a second-third recess 159-3, and a second-fourth recess 159-4 can be formed in the first side portion 1501, the second side portion 1502, the third side portion 1503, and the fourth side portion 1504 of the second semiconductor region 150-21, respectively, through additional etching. The recess 159 can be configured by the second-first recess 159-1, the second-second recess 159-2, the second-third recess 159-3, and the second-fourth recess 159-4.

In this case, the first angle θ1 of the second-first recess 159-1, the second angle θ2 of the second-second recess 159-2, the third angle θ3 of the second-third recess 159-3, and the fourth angle θ1 of the second-fourth recess 159-4 may be different from each other. That is, the first angle θ1 of the second-first recess 159-1 and the third angle θ3 of the second-third recess 159-3 may each have an acute angle, and the second angle θ2 of the second-second recess 159-2 and the fourth angle θ1 of the second-fourth recess 159-4 may each have an obtuse angle.

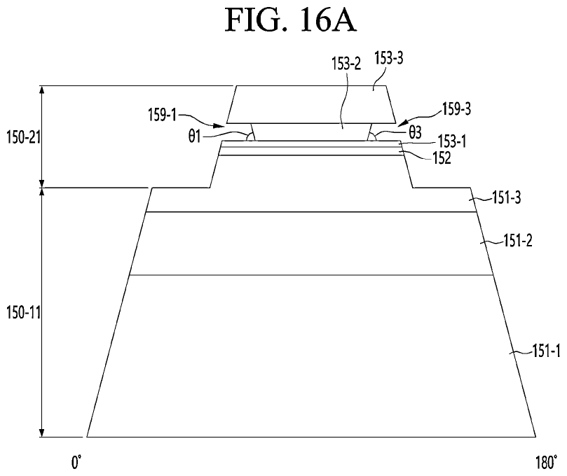

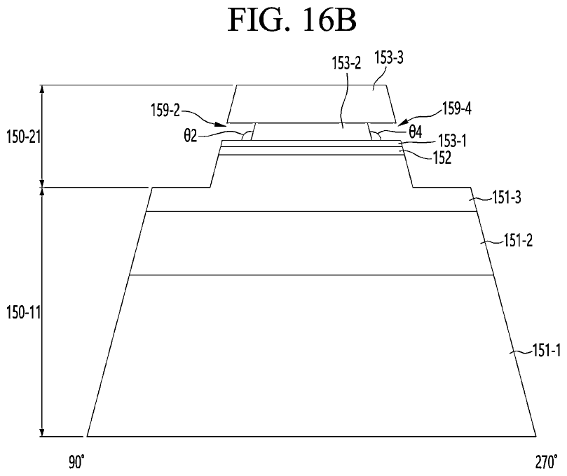

In the growth substrate 1000, the first side portion 1501 or the third side portion 1503 of the second semiconductor region 150-21 may be formed corresponding to the crystal orientation of 0° or 180°, respectively, and the second-first recess 159-1 or the second-third recess 159-3 may be formed in the first side portion 1501 or the third side portion 1503, respectively. In this case, as illustrated in FIG. 16a, the first angle θ1 of the second-first recess 159-1 or the third angle θ3 of the second-third recess 159-3 may have an acute angle. The first angle θ1 of the second-first recess 159-1 and the third angle θ3 of the second-third recess 159-3 may be the same.

In the growth substrate 1000, the second semiconductor region 150-21 may be formed with the second side portion 1502 or the fourth side portion 1504, respectively, corresponding to the crystal orientation of 90° or 270°, and the second-second recess 159-2 or the second-fourth recess 159-4 may be formed in the second side portion 1502 or the fourth side portion 1504, respectively. In this case, as illustrated in FIG. 16b, the second angle θ2 of the second-second recess 159-2 or the fourth angle θ1 of the second-fourth recess 159-4 may have an obtuse angle. The second angle θ2 of the second-second recess 159-2 and the fourth angle θ1 of the second-fourth recess may be the same.

In the first embodiment (FIGS. 7 and 8), along the outer peripheral surface of the semiconductor light-emitting element 150 or as the crystal orientation of the growth substrate 1000 increases from 0° to 360°, the angle of the recess 159 may vary in the order of acute angle→obtuse angle→acute angle→obtuse angle→acute angle. In contrast, in the second embodiment (FIGS. 12 to 16b), along the outer peripheral surface of the semiconductor light-emitting element 150A or as the crystal orientation of the growth substrate 1000 increases from 0° to 360°, the first angle θ1 of the second-first recess 159-1 and the third angle θ3 of the second-third recess 159-3 formed in the first side portion 1501 and the third side portion 1503 of the second semiconductor region 150-21, respectively, may have an acute angle. In addition, along the outer peripheral surface of the semiconductor light-emitting element 150A or as the crystal orientation of the growth substrate 1000 increases from 0° to 360°, the second angle θ2 of the second-second recess 159-2 and the fourth angle θ1 of the second-fourth recess 159-4 formed in the second side portion 1502 and the fourth side portion 1504 of the second semiconductor region 150-21, respectively, may have an obtuse angle.

In other words, in the first embodiment, the angle of the recess 159 may be variable, whereas in the second embodiment, the second-first recess 159-1, the second-second recess 159-2, the second-third recess 159-3, and the second-fourth recess 159-4 formed in the first side portion 1501, the second side portion 1502, the third side portion 1503, and the fourth side portion 1504, respectively, of the second semiconductor region 150-21 can have two different angles, i.e., an acute angle and an obtuse angle.

According to the embodiment, the second semiconductor region 150-21 can be made to have a rectangular shape, and the recess 159 can have two different angles on a plurality of side portions of the second semiconductor region 150-21. Accordingly, the light generated in the active layer 152 included in the second semiconductor region 150-21 can be reflected or diffused in more diverse directions by the second semiconductor region 150-21 having a rectangular shape as well as the recess 159 having different angles, thereby further improving the light efficiency.

Meanwhile, the first semiconductor region 150-11 may comprise a plurality of first semiconductor layers 151-1, 151-2, and 151-3. The second semiconductor region 150-21 may comprise an active layer 152 and a plurality of second semiconductor layers 153-1, 153-2, and 153-3.

The active layer 152 may be disposed on the plurality of first semiconductor layers 151-1, 151-2, and 151-3, and the plurality of second semiconductor layers 153-1, 153-2, and 153-3 may be disposed on the active layer 152. As illustrated in FIG. 13, some of the plurality of first semiconductor layers 151-1, 151-2, and 151-3 may be included in the first semiconductor region 150-11.

For example, the plurality of first semiconductor layers 151-1, 151-2, and 151-3 may have a circular shape, and the active layer 152 and the plurality of second semiconductor layers may have a rectangular shape. The recess 159 may be positioned on the active layer 152. The recess 159 may be disposed along the outer peripheral surface of one layer of the plurality of second semiconductor layers 153-1, 153-2, and 153-3.

The plurality of first semiconductor layers comprise the first-first semiconductor layer 151-1, the first-second semiconductor layer 151-2, and the first-third semiconductor layer 151-3, but there may be more layers than these. The plurality of second semiconductor layers 153-1, 153-2, and 153-3 comprise a second-first semiconductor layer 153-1, a second-second semiconductor layer 153-2, and a second-third semiconductor layer 153-3, but there may be more layers than these. Since these have been described above, detailed descriptions thereof will be omitted.

When the semiconductor light-emitting element 150A is a red light semiconductor light-emitting element, the semiconductor light-emitting element may be formed of a compound semiconductor material of the GaP series.

The etch rates of the semiconductor layer 151-1, the first-second semiconductor layer 151-2, and the first-third semiconductor layer 151-3 may be different from each other. For example, the etch rate of the first-second semiconductor layer 151-2 may be faster than the etch rate of the first-first semiconductor layer 151-1. For example, the etch rate of the first-second semiconductor layer 151-2 may be faster than the etch rate of the first-third semiconductor layer 151-3. The etch rates of the second-first semiconductor layer 153-1, the second-second semiconductor layer 153-2, and the second-third semiconductor layer 153-3 may be different from each other. For example, the etch rate of the second-second semiconductor layer 153-2 may be faster than the etch rate of the second-first semiconductor layer 153-1. For example, the etch rate of the second-second semiconductor layer 153-2 may be faster than the etch rate of the second-third semiconductor layer 153-3. Here, the etching refers to wet etching using an etchant.

The semiconductor layer 151-1 and the first-third semiconductor layer 151-3 may be made of the same compound semiconductor material, and the second-first semiconductor layer 153-1 and the second-third semiconductor layer 153-3 may be made of the same compound semiconductor material. For example, the first-first semiconductor layer 151-1, the first-third semiconductor layer 151-3, the second-first semiconductor layer 153-1, and the second-third semiconductor layer 153-3 may comprise AlGaInP. For example, the first-second semiconductor layer 151-2 and the second-second semiconductor layer 153-2 may comprise AlInP.

Meanwhile, after the second semiconductor region 150-21 of the rectangular shape is formed through mesa etching, wet etching can be performed. In this case, as described above, since the etch rate of the second-second semiconductor layer 153-2 is faster than the etch rate of the second-first semiconductor layer 153-1 or the etch rate of the second-third semiconductor layer 153-3, the second-second semiconductor layer 153-2 may be etched inward faster than the second-first semiconductor layer 153-1 or the second-third semiconductor layer 153-3, so that the recess 159 can be formed. In each of the first side portion 1501, the second side portion 1502, the third side portion 1503, and the fourth side portion 1504 of the second semiconductor region 150-21, the second-second semiconductor layer 153-2 may be etched inward faster than the second-first semiconductor layer 153-1 or the second-third semiconductor layer 153-3, so that the second-first recess 159-1, the second-second recess 159-2, the second-third recess 159-3, and the second-fourth recess 159-4 can be formed. Since the second-second semiconductor layer 153-2 is etched inward faster than the second-first semiconductor layer 153-1 or the second-third semiconductor layer 153-3, the upper surface of the second-first semiconductor layer 153-1, the side surface of the second-second semiconductor layer 153-2, and the lower surface of the second-third semiconductor layer 153-3 may be exposed. Accordingly, the recess 159 may have a bottom surface 159a, which is the upper surface of the second-first semiconductor layer 153-1, an inner surface 159b, which is the side surface of the second-second semiconductor layer 153-2, and a top surface 159c, which is the lower surface of the second-third semiconductor layer 153-3.

As described above, the angle of the inner surface 159b with respect to the bottom surface 159a may be defined as the angle of the recess 159. According to an embodiment, the first angle θ1 of the second-first recess 159-1, the second angle θ2 of the second-second recess 159-2, the third angle θ3 of the second-third recess 159-3, and the fourth angle θ1 of the second-fourth recess 159-4 may be different from each other. For example, the first angle θ1 of the second-first recess 159-1 and the third angle θ3 of the second-third recess 159-3 may be equal as acute angles. For example, the second angle θ2 of the second-second recess 159-2 and the fourth angle θ1 of the second-fourth recess 159-4 may be equal as obtuse angles.

Meanwhile, since the recess 159 is disposed along the outer peripheral surface of at least one semiconductor layer of the plurality of second semiconductor layers 153-1, 153-2, and 153-3, it may have a rectangular ring. For example, the recess 159 may be disposed along the outer peripheral surface of the second-second semiconductor layer 153-2. As described above, since the etch rate of the second-second semiconductor layer 153-2 comprising AlInP is faster than the etch rates of each of the second-first semiconductor layer 153-1 and the second-third semiconductor layer 153-3 comprising AlGalnP, when wet etching is performed by an etchant, the outer side portion of the second-second semiconductor layer 153-2 may be etched faster than the outer side portion of each of the second-first semiconductor layer 153-1 and the second-third semiconductor layer 153-3, so that the recess 159 can be formed. That is, the side portion of the second-second semiconductor layer 153-2 can be closer to the center of the semiconductor light-emitting element 150A than the side portion of the second-first semiconductor layer 153-1 and the side portion of the second-third semiconductor layer 153-3. In other words, the side portion of the second-second semiconductor layer 153-2 can be positioned further inwardly relative to each of the side portion of the second-first semiconductor layer 153-1 and the side portion of the second-third semiconductor layer 153-3, so that the recess 159 can be formed.

In other words, since the recess 159 is formed as the second-first recess 159-1, the second-second recess 159-2, the second-third recess 159-3, and the second-fourth recess 159-4, respectively, in the first side portion 1501, the second side portion 1502, the third side portion 1503, and the fourth side portion 1504 of the second semiconductor region 150-21, the recess 159 formed by these second-first recess 159-1, the second-second recess 159-2, the second-third recess 159-3, and the second-fourth recess 159-4 can have a rectangular ring.

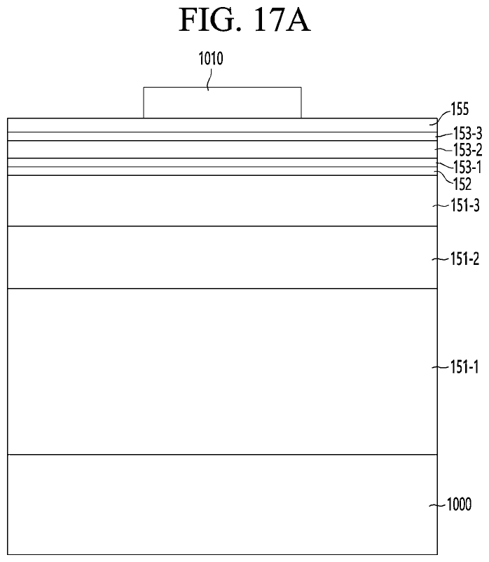

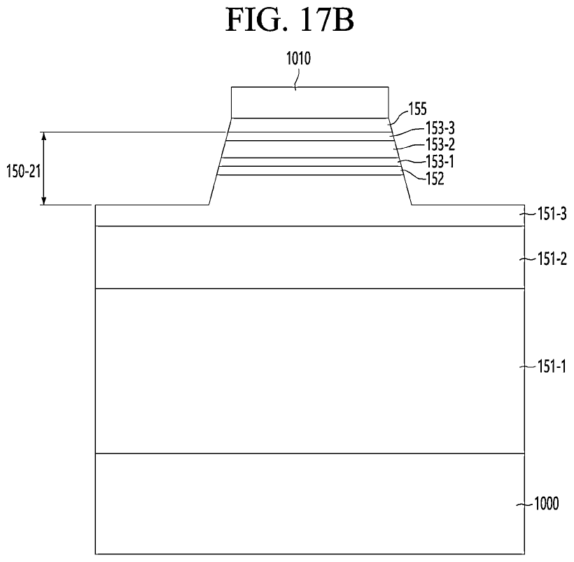

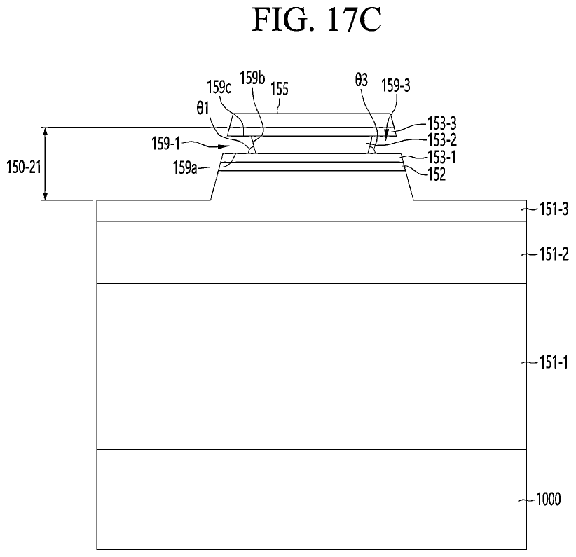

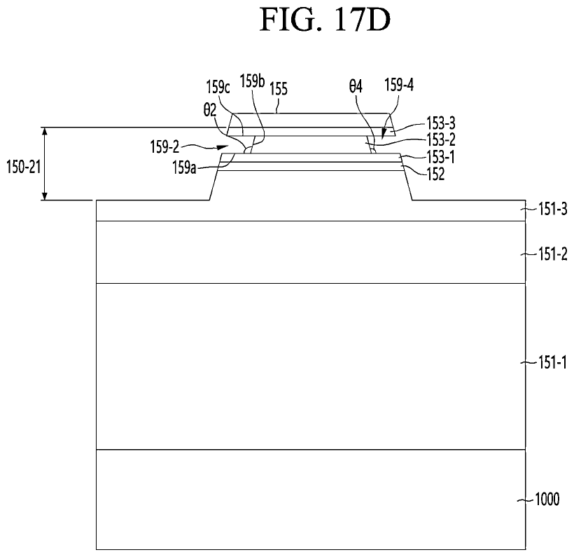

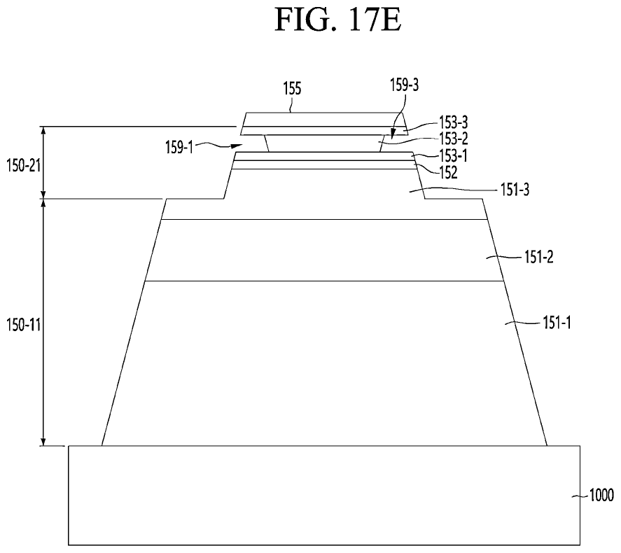

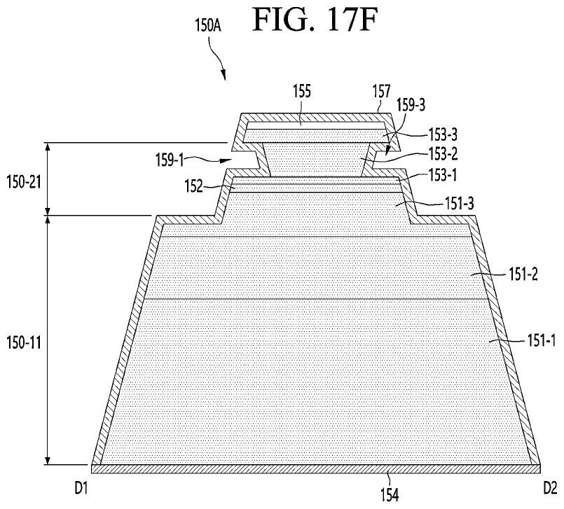

Hereinafter, a method for manufacturing a semiconductor light-emitting element according to the second embodiment will be described with reference to FIGS. 17A to 17F.

FIGS. 17A to 17F illustrate a method for manufacturing a semiconductor light-emitting element according to a second embodiment.

As illustrated in FIG. 17A, a plurality of first semiconductor layers 151-1, 151-2, and 151-3, an active layer 152, and a plurality of second semiconductor layers 153-1, 153-2, and 153-3 may be deposited on a growth substrate 1000.

Thereafter, a second electrode 155 may be formed on the plurality of second semiconductor layers 153-1, 153-2, and 153-3, and a photosensitive pattern 1010 may be formed on the second electrode 155. The photosensitive pattern 1010 may have a rectangular shape when viewed from above.

As illustrated in FIG. 17b, dry etching may be performed using the photosensitive pattern 1010 as a mask to remove the second electrode 155, the plurality of second semiconductor layers 153-1, 153-2, and 153-3, and the active layer 152. At this time, some among the plurality of first semiconductor layers 151-1, 151-2, and 151-3 may be removed. The remaining layers after dry etching may have a rectangular shape when viewed from above and may be defined as the second semiconductor region 150-21.

As illustrated in FIG. 17c and FIG. 17d, the growth substrate 1000 may be immersed in an etchant and wet etching may be performed.

The plurality of second semiconductor layers 153-1, 153-2, and 153-3 may be etched by the etchant. The plurality of second semiconductor layers 153-1, 153-2, and 153-3 may comprise the second-first semiconductor layer 153-1, the second-second semiconductor layer 153-2, and the second-third semiconductor layer 153-3. The second-second semiconductor layer 153-2 may be a material that is relatively well etched by an etchant, such as AlInP, and the second-first semiconductor layer 153-1 or the second-third semiconductor layer 153-3 may be a material that is relatively poorly etched, such as AlGalnP.

When the growth substrate 1000 is immersed in the etchant, among the plurality of second semiconductor layers 153-1, 153-2, and 153-3, the second-second semiconductor layer 153-2 may be removed more quickly than the second-first semiconductor layer 153-1 or the second-third semiconductor layer 153-3. Accordingly, the second-second semiconductor layer 153-2 can be etched inward faster than the second-first semiconductor layer 153-1 or the second-third semiconductor layer 153-3, so that the recesses 159-1, 159-2, 159-3, and 159-4 can be formed. That is, when the growth substrate 1000 is immersed in the etchant, as illustrated in FIG. 12b, the second-first recess 159-1, the second-second recess 159-2, the second-third recess 159-3, and the second-fourth recess 159-4 can be formed in the first side portion 1501, the second side portion 1502, the third side portion 1503, and the fourth side portion 1504 of the second semiconductor region 150-21, respectively.

Before wet etching is performed, the photosensitive pattern 1010 may be removed, but is not limited thereto.

As shown in FIG. 17e, dry etching may be performed to form a first semiconductor region 150-11 having a circular shape.

After a photosensitive film is formed on the growth substrate 1000, a photosensitive pattern (not shown) having a circular shape may be formed through exposure and development. By performing dry etching using the photosensitive pattern having a circular shape as a mask, a plurality of first semiconductor layers 151-1, 151-2, and 151-3 may be removed. The dry etching may be performed until the growth substrate 1000 is exposed, but is not limited thereto.

A plurality of light-emitting portions 151-1, 151-2, 151-3, 152, 153-1, 153-2, and 153-3 spaced apart from each other can be formed by such dry etching.

As illustrated in FIG. 17f, after a circular photosensitive pattern is removed, a passivation layer 157 can be formed around each of the plurality of light-emitting portions 151-1, 151-2, 151-3, 152, 153-1, 153-2, and 153-3.

Thereafter, a first electrode 154 can be formed under each of the plurality of light-emitting portions 151-1, 151-2, 151-3, 152, 153-1, 153-2, and 153-3.

For example, after a plurality of light-emitting portions 151-1, 151-2, 151-3, 152, 153-1, 153-2, and 153-3 are attached to another substrate, an LLO process may be performed to remove the growth substrate 1000. Thereafter, a first electrode 154 may be formed under each of the plurality of light-emitting portions 151-1, 151-2, 151-3, 152, 153-1, 153-2, and 153-3 that are exposed by removing the growth substrate 1000.

Although not shown, when an undoped semiconductor layer is formed on the growth substrate 1000 during the growth of the plurality of light-emitting portions 151-1, 151-2, 151-3, 152, 153-1, 153-2 and 153-3, the undoped semiconductor layer may be removed through an etching process after the growth substrate 1000 is removed, so that the lowermost layer of the plurality of first semiconductor layers 151-1, 151-2 and 151-3 may be exposed, but is not limited thereto. The undoped semiconductor layer may be a seed layer for growing the plurality of light-emitting portions 151-1, 151-2, 151-3, 152, 153-1, 153-2 and 153-3, and may have a lattice constant similar to a lattice constant of the growth substrate 1000.

### Third Embodiment

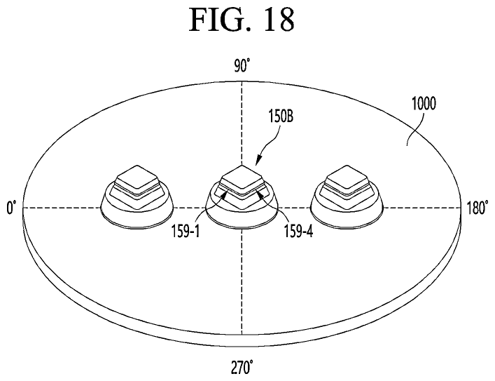

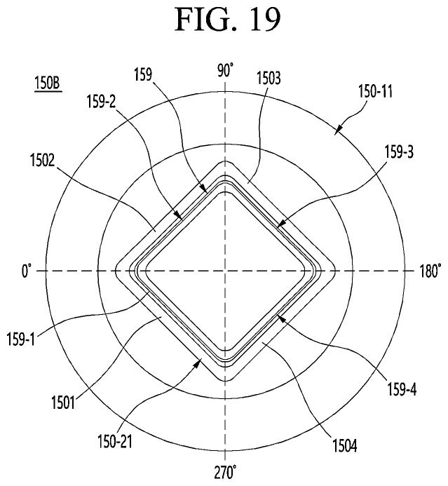

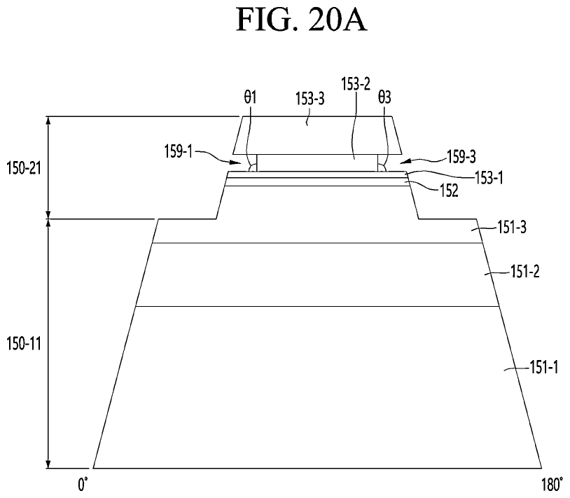

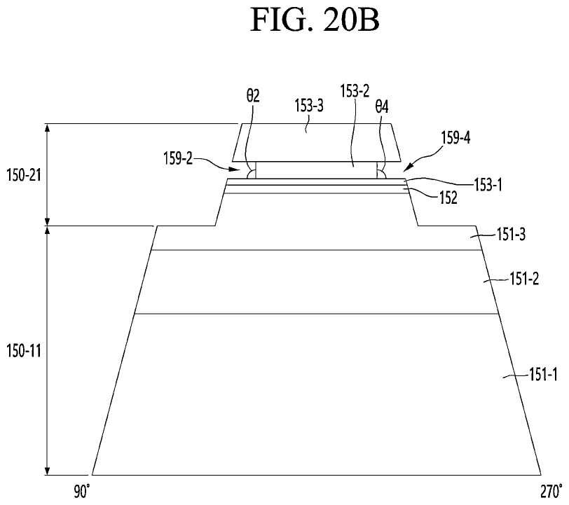

FIG. 18 illustrates the crystal orientation of the growth substrate 1000 and the positional relationship of the second semiconductor region 150-21 of the semiconductor light-emitting element according to a third embodiment. FIG. 19 illustrates the crystal orientation of the growth substrate 1000 and the positional relationship of the second semiconductor region 150-21 of the semiconductor light-emitting element according to the third embodiment. FIG. 20a is a cross-sectional view taken along the crystal orientation of the growth substrate 1000 between 0° and 180°. FIG. 20b is a cross-sectional view taken along the crystal orientation of the growth substrate 1000 between 90° and 270°.

The embodiment is the same as the second embodiment except that when the second-first recess 159-1, the second-second recess 159-2, the second-third recess 159-3, and the second-fourth recess 159-4 are provided in the first side portion 1501, the second side portion 1502, the third side portion 1503, and the fourth side portion 1504 of the second semiconductor region 150-21, respectively, the first angle θ1 of the second-first recess 159-1, the second angle θ2 of the second-second recess 159-2, the third angle θ3 of the second-third recess 159-3, and the fourth angle θ1 of the second-fourth recess 159-4 are the same. In the third embodiment, the same drawing reference numerals are given to components having the same structure, shape, and/or function as those of the first embodiment, and detailed descriptions are omitted.

As illustrated in FIG. 18, a plurality of semiconductor light-emitting elements 150B can be manufactured on a growth substrate 1000. At this time, the growth of each of the plurality of semiconductor layers of the plurality of semiconductor light-emitting elements 150B is affected by the crystal orientation of the growth substrate 1000.

The growth substrate 1000 can have a crystal orientation from 0° to 360°. For example, when the growth substrate 1000 is made of sapphire, the crystal orientation of the sapphire can be determined from 0° to 360°.

A plurality of semiconductor light-emitting elements 150B can be manufactured on a growth substrate 1000 having such a crystal orientation. That is, after a plurality of semiconductor layers are deposited on a growth substrate 1000 having a preset crystal orientation, mesa etching may be performed to manufacture a plurality of semiconductor light-emitting elements 150B, so that a first semiconductor region 150-11 having a circular shape and a second semiconductor region 150-21 having a rectangular shape can be formed.

For example, as illustrated in FIG. 19, the crystal orientations of the growth substrate 1000 may correspond to the corners of the first side portion 1501, the second side portion 1502, the third side portion 1503, and the fourth side portion 1504 of the second semiconductor region 150-21 at 0°, 90°, 180°, and 270°, respectively. That is, when the crystal orientation of the growth substrate 1000 is 0°, the corners formed by the first side portion 1501 and the second side portion 1502 of the second semiconductor region 150-21 can be in contact. When the crystal orientation of the growth substrate 1000 is 90°, the corners formed by the second side portion 1502 and the third side portion 1503 of the second semiconductor region 150-21 can be in contact. When the crystal orientation of the growth substrate 1000 is 180°, the corners formed by the third side portion 1503 and the fourth side portion 1504 of the second semiconductor region 150-21 can be in contact. When the crystal orientation of the growth substrate 1000 is 270°, the corners formed by the first side portion 1501 and the fourth side portion 1504 of the second semiconductor region 150-21 can be in contact. At this time, through additional etching, a second-first recess 159-1, a second-second recess 159-2, a second-third recess 159-3, and a second-fourth recess 159-4 can be formed in the first side portion 1501, the second side portion 1502, the third side portion 1503, and the fourth side portion 1504, respectively, of the second semiconductor region 150-21. The recess 159 can be configured by the second-first recess 159-1, the second-second recess 159-2, the second-third recess 159-3, and the second-fourth recess 159-4.

In this case, the first angle θ1 of the second-first recess 159-1, the second angle θ2 of the second-second recess 159-2, the third angle θ3 of the second-third recess 159-3, and the fourth angle θ1 of the second-fourth recess 159-4 may be the same. For example, the first angle θ1 of the second-first recess 159-1, the second angle θ2 of the second-second recess 159-2, the third angle θ3 of the second-third recess 159-3, and the fourth angle θ1 of the second-fourth recess 159-4 may be 90°, respectively, but are not limited thereto.

In the embodiments (FIGS. 12 to 16b), along the outer peripheral surface of the semiconductor light-emitting element 150A or as the crystal orientation of the growth substrate 1000 increases from 0° to 360°, the first angle θ1 of the second-first recess 159-1 and the third angle θ3 of the second-third recess 159-3 formed in the first side portion 1501 and the third side portion 1503, respectively, of the second semiconductor region 150-21 may have acute angles. In addition, along the outer peripheral surface of the semiconductor light-emitting element 150A or as the crystal orientation of the growth substrate 1000 increases from 0° to 360°, the second angle θ2 of the second-second recess 159-2 and the fourth angle θ1 of the second-fourth recess 159-4 formed in the second side portion 1502 and the fourth side portion 1504, respectively, of the second semiconductor region 150-21 may have obtuse angles. In contrast, in the third embodiment (FIGS. 18 to 20b), along the outer peripheral surface of the semiconductor light-emitting element 150B or as the crystal orientation of the growth substrate 1000 increases from 0° to 360°, the first angle θ1 of the second-first recess 159-1, the second angle θ2 of the second-second recess 159-2, the third angle θ3 of the second-third recess 159-3, and the fourth angle θ1 of the second-fourth recess 159-4 formed in the first side portion 1501, the second side portion 1502, the third side portion 1503, and the fourth side portion 1504, respectively, of the second semiconductor region 150-21 may be the same.

In other words, in the second embodiment, the second-first recess 159-1, the second-second recess 159-2, the second-third recess 159-3 and the second-fourth recess 159-4 formed in the first side portion 1501, the second side portion 1502, the third side portion 1503 and the fourth side portion 1504, respectively, of the second semiconductor region 150-21 may have two different angles, i.e., an acute angle and an obtuse angle. In contrast, in the third embodiment, the second-first recess 159-1, the second-second recess 159-2, the second-third recess 159-3, and the second-fourth recess 159-4 formed in the first side portion 1501, the second side portion 1502, the third side portion 1503, and the fourth side portion 1504, respectively, of the second semiconductor region 150-21 may be the same.

According to the embodiment, the second semiconductor region 150-21 may have a rectangular shape, and the recess 159 may have the same angle on a plurality of side portions of the second semiconductor region 150-21. Therefore, the light generated in the active layer 152 included in the second semiconductor region 150-21 can be reflected or diffused in more diverse directions by the recess 159 having the same angle in the plurality of side portions of the second semiconductor region 150-21 as well as the second semiconductor region 150-21 having a rectangular shape, thereby further improving light efficiency.

### Fourth Embodiment

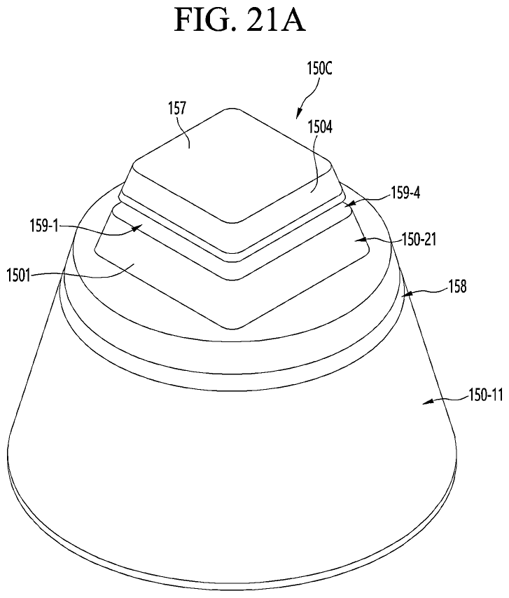

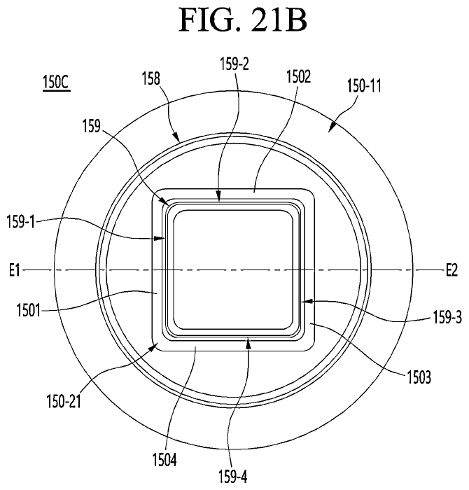

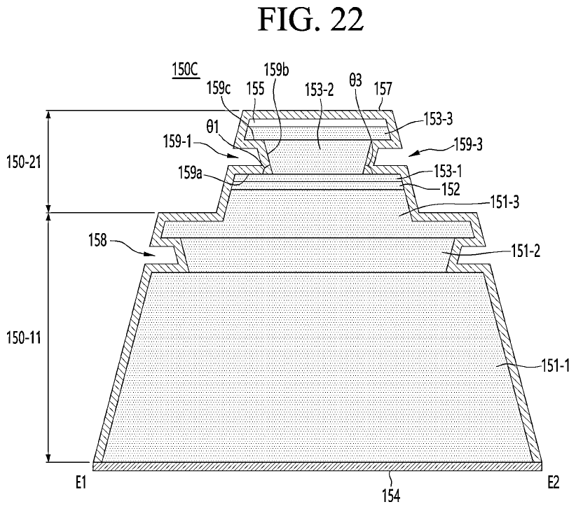

FIG. 21a is a perspective view illustrating a semiconductor light-emitting element according to a fourth embodiment. FIG. 21b is a plan view illustrating a semiconductor light-emitting element according to the fourth embodiment. FIG. 22 is a cross-sectional view of the semiconductor light-emitting element according to the fourth embodiment of FIG. 21b taken along the line E1-E2.

The embodiment is the same as the second and third embodiments except for the first recess 158. In the fourth embodiment, the same drawing reference numerals are given to components having the same structure, shape, and/or function as those of the first embodiment, and detailed descriptions are omitted.

Referring to FIGS. 21a to 22, the semiconductor light-emitting element 150C according to the fourth embodiment may comprise a first semiconductor region 150-11, a second semiconductor region 150-21, at least one or more first recess 158, and at least one or more second recess 159.

The first semiconductor region 150-11 may have a first shape, and the second semiconductor region 150-21 may have a second shape. When viewed from above, the first shape may have a circular shape, and the second shape may have a rectangular shape.

The at least one or more first recess 158 may be disposed along an outer peripheral surface of the first semiconductor region 150-11, and the at least one or more second recess 159 may be disposed along an outer peripheral surface of the second semiconductor region 150-21.

Meanwhile, the plurality of first semiconductor layers comprise the first-first semiconductor layer 151-1, the first-second semiconductor layer 151-2, and the first-third semiconductor layer 151-3, but there may be more layers than these. The plurality of second semiconductor layers 153-1, 153-2, and 153-3 comprise the second-first semiconductor layer 153-1, the second-second semiconductor layer 153-2, and the second-third semiconductor layer 153-3, but there may be more layers than these.

The semiconductor layer 151-1 and the first-second semiconductor layer 151-2 may each comprise a first dopant, and the second-second semiconductor layer 153-2 and the second-third semiconductor layer 153-3 may each comprise a second dopant. For example, the first dopant may be silicon (Si), etc., and the second dopant may be magnesium (Mg), etc. The first-third semiconductor layer 151-3 and the second-first semiconductor layer 153-1 may be cladding layers. The first-third semiconductor layer 151-3 and the second-first semiconductor layer 153-1 may each be undoped semiconductor layers.

The semiconductor layer 151-2 may comprise a relatively well-etchable material, such as AlInP, and the first-first semiconductor layer 151-1 or the first-third semiconductor layer 151-3 may comprise a relatively poor-etchable material, such as AlGaInP. The second-second semiconductor layer 153-2 may comprise a relatively well-etchable material, such as AlInP, and the second-first semiconductor layer 153-1 or the second-third semiconductor layer 153-3 may comprise a relatively poor-etchable material, such as AlGaInP.

For example, when a plurality of first semiconductor layers 151-1, 151-2, and 151-3, an active layer 152, and a plurality of second semiconductor layers 153-1, 153-2, and 153-3 are immersed in an etchant, the first-second semiconductor layer 151-2 may be removed faster than the first-first semiconductor layer 151-1 or the first-third semiconductor layer 151-3, so that first recess 158 can be formed. That is, the first recess 158 may be formed along an outer peripheral surface of the first-second semiconductor layer 151-2. The first-second semiconductor layer 151-2 may be etched inwardly so that the upper surface of the first-first semiconductor layer 151-1 and the lower surface of the first-third semiconductor layer 151-3 can be exposed, so that a first recess 158 can be formed by the upper surface of the first-first semiconductor layer 151-1, the side surface of the first-second semiconductor layer 151-2, and the lower surface of the first-third semiconductor layer 151-3.

As described above, since the etch rate of the first-second semiconductor layer 151-2 comprising AlInP is faster than the etch rates of each of the first-first semiconductor layer 151-1 and the first-third semiconductor layer 151-3 comprising AlGalnP, when wet etching is performed by an etchant, the outer side portion of the first-second semiconductor layer 151-2 can be etched faster than the outer side portion of each of the first-first semiconductor layer 151-1 and the first-third semiconductor layer 151-3, so that the first recess 158 can be formed. That is, the side portion of the first-second semiconductor layer 151-2 can be closer to the center of the semiconductor light-emitting element 150C than the side portions of the first-first semiconductor layer 151-1 and the first-third semiconductor layer 151-3. In other words, the side portion of the first-second semiconductor layer 151-2 may be positioned more inwardly relative to the side portion of the first-first semiconductor layer 151-1 and the side portion of the first-third semiconductor layer 151-3, respectively, so that the recess 159 can be formed.

Since the first recess 158 is formed along the outer peripheral surface of the first semiconductor region 150-11 having a circular shape, i.e., the first-second semiconductor layer 151-2, the angle θ21 of the first recess 158 can be varied along the outer peripheral surface of the first-second semiconductor layer 151-2. For example, the angle θ21 of the first recess 158 can be varied in the order of acute angle→obtuse angle→acute angle→obtuse angle→acute angle along the outer peripheral surface of the first-second semiconductor layer 151-2. The first recess 158 may comprise a bottom surface 158a, an inner surface 158b, and a top surface 158c. At this time, the angle θ11 of the first recess 158 may be an angle of the inner surface 158b with respect to the bottom surface 158a.

For example, when a plurality of first semiconductor layers 151-1, 151-2, and 151-3, an active layer 152, and a plurality of second semiconductor layers 153-1, 153-2, and 153-3 are immersed in an etchant, the second-second semiconductor layer 153-2 may be removed faster than the second-first semiconductor layer 153-1 or the second-third semiconductor layer 153-3, so that the second recess 159 can be formed. That is, the second recess 159 may be formed along an outer peripheral surface of the second-second semiconductor layer 153-2. The second-second semiconductor layer 153-2 may be etched inwardly to expose the upper surface of the second-first semiconductor layer 153-1 and the lower surface of the second-third semiconductor layer 153-3, so that a second recess 159 can be formed by the upper surface of the second-first semiconductor layer 153-1, the side surface of the second-second semiconductor layer 153-2, and the lower surface of the second-third semiconductor layer 153-3.

The recess 159 can be formed along the outer peripheral surface of the second semiconductor region 150-21 having a rectangular shape, i.e., the second-second semiconductor layer 153-2.

As an example, as illustrated in FIGS. 14 and 15, when the first side portion 1501, the second side portion 1502, the third side portion 1503, and the fourth side portion 1504 of the semiconductor light-emitting element 150A are in contact with crystal orientations of 0°, 90°, 180°, and 270° in the growth substrate 1000, respectively, the first angle θ1 of the second-first recess 159-1 on the first side portion 1501, the second angle θ2 of the second-second recess 159-2 on the second side portion 1502, the third angle θ3 of the second-third recess 159-3 on the third side portion 1503, and the fourth angle θ1 of the second-fourth recess 159-4 on the fourth side portion 1504 may be different. For example, the first angle θ1 of the second-first recess 159-1 and the third angle θ3 of the second-third recess 159-3 may have acute angles (FIG. 16a), and the second angle θ2 of the second-second recess 159-2 and the fourth angle θ1 of the second-fourth recess 159-4 may have obtuse angles (FIG. 16b). Similarly, in the second recess 159 of the semiconductor light-emitting element 150C of the embodiment, the first angle θ1 of the second-first recess 159-1 and the third angle θ3 of the second-third recess 159-3 may have acute angles, and the second angle θ2 of the second-second recess 159-2 and the fourth angle θ1 of the second-fourth recess 159-4 may have obtuse angles.

As another example, as illustrated in FIGS. 18 and 19, when the corners between the first side portion 1501, the second side portion 1502, the third side portion 1503, and the fourth side portion 1504 of the semiconductor light-emitting element 150B are in contact with crystal orientations of 0°, 90°, 180°, and 270° in the growth substrate 1000, respectively, the first angle θ1 of the second-first recess 159-1 on the first side portion 1501, the second angle θ2 of the second-second recess 159-2 on the second side portion 1502, the third angle θ3 of the second-third recess 159-3 on the third side portion 1503, and the fourth angle θ1 of the second-fourth recess 159-4 on the fourth side portion 1504 may be the same. For example, the first angle θ1 of the second-first recess 159-1, the second angle θ2 of the second-second recess 159-2, the third angle θ3 of the second-third recess 159-3, and the fourth angle θ1 of the second-fourth recess 159-4 may be 90°, but are not limited thereto. Similarly, in the semiconductor light-emitting element 150C of the embodiment, the first angle θ1 of the second-first recess 159-1, the second angle θ2 of the second-second recess 159-2, the third angle θ3 of the second-third recess 159-3, and the fourth angle θ1 of the second-fourth recess 159-4 may be 90°, but are not limited thereto.

Meanwhile, the first recess 158 may have a circular ring, and the second recess 159 may have a rectangular ring. At this time, as illustrated in FIG. 21b, the rectangular ring may be positioned within the circular ring. In addition, the first recess 158 may be positioned below the active layer 152, and the second recess 159 may be positioned above the active layer 152.

Meanwhile, the first recess 158 and the second recess 159 may be formed independently or simultaneously.

As an example, after dry etching is performed to form the second semiconductor region 150-21 having a rectangular shape, wet etching may be performed to form the second recess 159. Thereafter, dry etching may be performed to form the first semiconductor region 150-11 having a circular shape, and wet etching may be performed to form the first recess 158. When the first recess 158 is formed, the second recess 159 may be protected by a separate protective film or protective layer to protect the second recess. After the first recess 158 is formed, the protective film or protective layer may be removed.

As another example, after the first dry etching is performed to form the second semiconductor region 150-21 having a rectangular shape, the second dry etching may be performed to form the first semiconductor region 150-11 having a circular shape. Thereafter, the first recess 158 and the second recess 159 may be simultaneously formed by performing wet etching.

According to an embodiment, light generated in the active layer 152 may be reflected or diffused in more diverse directions by the second recess 159 formed in the second semiconductor region 150-21 as well as the first recess 158 formed in the first semiconductor region 150-11, so that the light efficiency can be significantly improved.

According to an embodiment, as illustrated in FIG. 24, when the side portion of the first semiconductor region 150-11 is connected to the first assembling wiring or the second assembling wiring through the connection electrode 370, the connection electrode 370 can be in contact with not only the side portion of the first semiconductor region 150-11 but also the first recess 158. In particular, since the connection electrode 370 is formed inside the first recess 158, the bonding force between the connection electrode 370 and the semiconductor light-emitting element 150C may be strengthened, so that the fixation of the semiconductor light-emitting element 150C can be improved, thereby improving the product reliability.

### [Display Device]

FIG. 23 is a plan view illustrating a display device according to an embodiment. FIG. 24 is a cross-sectional view taken along the C1-C2 line of FIG. 23.

Referring to FIGS. 23 and 24, the display device 300 according to an embodiment may comprise a substrate 310, a plurality of first assembling wirings 321, a plurality of second assembling wirings 322, a partition wall 340, a plurality of semiconductor light-emitting elements 150-1, 150-2, and 150-3, and a plurality of connection electrodes 370.

A plurality of sub-pixels PX1, PX2, and PX3 may be arranged on the substrate 310.

The plurality of sub-pixels may comprise a plurality of first sub-pixels PX1 arranged along a first direction X. The plurality of first sub-pixels PX1 can each emit the same color light, i.e., the first color light.

For example, the plurality of sub-pixels can comprise a plurality of second sub-pixels PX2 adjacent to the plurality of first sub-pixels PX1 along the second direction Y and arranged along the first direction X. The plurality of second sub-pixels PX2 can each emit the same color light, i.e., the second color light.

For example, the plurality of sub-pixels can comprise a plurality of third sub-pixels PX3 adjacent to the plurality of second sub-pixels PX2 along the second direction Y and arranged along the first direction X. The plurality of third sub-pixels PX3 can emit the same color light, i.e., the third color light.

The first color light may be red light, the second color light may be green light, and the third color light may be blue light, but are not limited thereto. The first sub-pixel PX1, the second sub-pixel PX2, and the third sub-pixel PX3 arranged along the second direction Y can form a unit pixel capable of displaying a full color image. Therefore, by arranging a plurality of unit pixels on the substrate 310, a large-area image can be displayed.

As illustrated in FIG. 24, the first sub-pixel PX1 can comprise a first assembling wiring 321, a second assembling wiring 322, an assembly hole 340H, a first semiconductor light-emitting element 150-1, a connection electrode 370, and an electrode wiring 362. Although not illustrated, the second sub-pixel PX2 and the third sub-pixel PX3 can also comprise the components of the first sub-pixel PX1 as they are.

Although not illustrated, the second sub-pixel PX2 and the third sub-pixel PX3 can also comprise the components illustrated in FIG. 24. However, the second semiconductor light-emitting element 150-2 may be disposed in the second sub-pixel PX2, and the third semiconductor light-emitting element 150-3 may be disposed in the third sub-pixel PX3.

The substrate 310 may be a supporting member that supports components disposed on the substrate 310 or a protective member that protects the components. Since the substrate 310 has been described above, it is omitted.

The first and second assembling wirings 321 and 322 may be disposed on the substrate 310. That is, the plurality of sub-pixels PX1, PX2, and PX3 may each comprise the first assembling wiring 321 and the second assembling wiring 322. The first and second assembling wirings 321 and 322 may play a role in assembling the semiconductor light-emitting element 150-1 into the assembly hole 340H in a self-assembly manner. That is, when self-assembling, an electric field may be generated between the first assembling wiring 321 and the second assembling wiring 322 by the voltage supplied to the first and second assembling wirings 321 and 322, and the semiconductor light-emitting element 150-1 moving by the assembly device (1100 of FIG. 10) can be assembled into the assembly hole 340H by the dielectrophoretic force formed by the electric field.

The same assembling wirings of each of the plurality of sub-pixels PX1, PX2, and PX3 can be formed integrally. For example, the second assembling wiring 322 of the first sub-pixel PX1 can be formed integrally with the second assembling wiring 322 of the second sub-pixel PX2. For example, the first assembling wiring 321 of the second sub-pixel PX2 can be formed integrally with the first assembling wiring 321 of the third sub-pixel PX3.

The first assembling wiring 321 and the second assembling wiring 322 may be disposed on the same layer. That is, the first assembling wiring 321 and the second assembling wiring 322 may be disposed between the substrate 310 and the first insulating layer 320. In this case, the first assembling wiring 321 and the second assembling wiring 322 may be disposed to be spaced apart from each other to prevent electrical-short circuit.

Although the drawing shows that the first assembling wiring 321 and the second assembling wiring 322 are disposed on the same layer, they may be disposed on different layers.

For example, the first assembling wiring 321 may be disposed under the first insulating layer 320, and the second assembling wiring 322 may be disposed on the first insulating layer 320. In this case, the upper surface of the second assembling wiring 322 may be exposed to the outside, that is, to the assembly hole 340H. For example, the second assembling wiring 322 may form a part of a bottom portion of the assembly hole 340H. When the semiconductor light-emitting element 150-1 is assembled in the assembly hole 340H, the lower side of the semiconductor light-emitting element 150-1 may come into contact with the upper surface of the second assembling wiring 322 in the assembly hole 340H.

Referring again to FIG. 12, the first insulating layer 320 may be disposed on the first assembling wiring 321 and the second assembling wiring 322. For example, the first insulating layer 320 may prevent the first assembling wiring 321 and the second assembling wiring 322 from being electrically short-circuited by foreign substances. For example, the first insulating layer 320 may be made of a material having a permittivity, and may contribute to the formation of a dielectrophoretic force. For example, the first insulating layer 320 may be made of an inorganic material or an organic material. For example, the first insulating layer 320 may be formed of a material having a permittivity related to a dielectrophoretic force.

The partition wall 340 may be disposed on the substrate 310 and may have an assembly hole 340H. Each of the plurality of sub-pixels PX1, PX2, and PX3 may comprise at least one or more assembly hole 340H. The partition wall 340 may be disposed on the first assembling wiring 321 and the second assembling wiring 322. For example, the assembly hole 340H may be provided on the first assembling wiring 321 and the second assembling wiring 322. The thickness of the partition wall 340 may be determined in consideration of the thickness of the semiconductor light-emitting element 150-1. For example, the thickness of the partition wall 340 may be smaller than the thickness of the semiconductor light-emitting element 150-1. Accordingly, an upper side of the semiconductor light-emitting element 150-1 may be positioned higher than an upper surface of the partition wall 340. That is, the upper side of the semiconductor light-emitting element 150-1 can protrude upward from the upper surface of the partition wall 340.

Each of the plurality of semiconductor light-emitting elements 150-1, 150-2 and 150-3 can be assembled into the assembly hole 340H by the dielectric force formed between the first assembling wiring 321 and the second assembling wiring 322 in the plurality of sub-pixels PX1, PX2 and PX3, respectively. For example, one semiconductor light-emitting element can be assembled into the assembly hole 340H.

The size of the assembly hole 340H can be determined by considering a tolerance margin for forming the assembly hole 340H and a margin for easily assembling the semiconductor light-emitting element 150-1, 150-2, and 150-3 within the assembly hole 340H. For example, the size of the assembly hole 340H can be greater than the size of the semiconductor light-emitting element 150-1, 150-2, and 150-3. For example, when the semiconductor light-emitting element 150-1, 150-2, and 150-3 is assembled at the center of the assembly hole 340H, the distance between the outer side surface of the semiconductor light-emitting element 150-1, 150-2, and 150-3 and the inner side surface of the assembly hole 340H may be 2 μm or less, but is not limited thereto.

For example, the assembly hole 340H may have a shape corresponding to the shape of the semiconductor light-emitting element 150-1, 150-2, and 150-3. For example, when the semiconductor light-emitting element 150-1, 150-2, and 150-3 has a circular shape, the assembly hole 340H may also be circular. For example, when the semiconductor light-emitting element 150-1, 150-2, and 150-3 has a rectangular shape, the assembly hole 340H may also have a rectangular shape.

As an example, the assembly holes 340H in the first sub-pixel PX1, the second sub-pixel PX2, and the third sub-pixel PX3, respectively, may have the same shape, i.e., a circular shape. In this case, the first semiconductor light-emitting element 150-1 disposed in the first sub-pixel PX1, the second semiconductor light-emitting element 150-2 disposed in the second sub-pixel PX2, and the third semiconductor light-emitting element 150-3 disposed in the third sub-pixel PX3 may have a shape corresponding to the assembly hole 340H, i.e., a circular shape.

In this way, when the assembly holes 340H of the first sub-pixel PX1, the second sub-pixel PX2, and the third sub-pixel PX3 have the same shape, the first semiconductor light-emitting element 150-1, the second semiconductor light-emitting element 150-2, and the third semiconductor light-emitting element 150-3 can be sequentially assembled into the assembly holes 340H of the corresponding sub-pixels PX1, PX2, and PX3, but are not limited thereto. For example, the first semiconductor light-emitting element 150-1 can be assembled into the assembly hole 340H of the first sub-pixel PX1 of the substrate 310, the second semiconductor light-emitting element 150-2 can be assembled into the assembly hole 340H of the second sub-pixel PX2 of the substrate 310, and the third semiconductor light-emitting element 150-3 can be assembled into the assembly hole 340H of the third sub-pixel PX3 of the substrate 310. In this case, the shapes of the first semiconductor light-emitting element 150-1, the second semiconductor light-emitting element 150-2, and the third semiconductor light-emitting element 150-3 may be the same, but are not limited thereto. The assembly holes 340H may have shapes corresponding to the shapes of the first semiconductor light-emitting element 150-1, the second semiconductor light-emitting element 150-2, and the third semiconductor light-emitting element 150-3, respectively, but may have sizes greater than the sizes of the first semiconductor light-emitting element 150-1, the second semiconductor light-emitting element 150-2, and the third semiconductor light-emitting element 150-3, respectively.

As another example, the assembly holes 340H in the first sub-pixel PX1, the second sub-pixel PX2, and the third sub-pixel PX3 may have different shapes. For example, the assembly hole 340H in the first sub-pixel PX1 may have a circular shape, the assembly hole 340H in the second sub-pixel PX2 may have a first oval shape having a first minor axis and a first major axis, and the assembly hole 340H in the third sub-pixel PX3 may have a second oval shape having a second minor axis smaller than the first minor axis and a second major axis greater than the first major axis. In this case, the first semiconductor light-emitting element 150-1 may have a shape corresponding to the assembly hole 340H of the first sub-pixel PX1, that is, a circular shape, the second semiconductor light-emitting element 150-2 may have a shape corresponding to the assembly hole 340H of the second sub-pixel PX2, that is, a first oval shape, and the third semiconductor light-emitting element 150-3 may have a shape corresponding to the assembly hole 340H of the third sub-pixel PX3, that is, a second oval shape.

In this way, by means of the assembly holes 340H having different shapes and the first to third semiconductor light-emitting elements 150-1, 150-2 and 150-3 having shapes corresponding to the assembly holes 340H, the first to third semiconductor light-emitting elements 150-1, 150-2 and 150-3 can be assembled into the corresponding assembly holes 340H at the same time during self-assembly. That is, even if the first semiconductor light-emitting element 150-1, the second semiconductor light-emitting element 150-2 and the third semiconductor light-emitting element 150-3 are mixed in the fluid 1200 for self-assembly, the semiconductor elements corresponding to the assembly holes 340H of the first sub-pixel PX1, the second sub-pixel PX2 and the third sub-pixel PX3 on the substrate can be assembled. That is, a first semiconductor light-emitting element 150-1 having a shape corresponding to the shape of the assembly hole 340H of the first sub-pixel PX1 can be assembled into the assembly hole 340H of the first sub-pixel PX1. A second semiconductor light-emitting element 150-2 having a shape corresponding to the shape of the assembly hole 340H can be assembled into the assembly hole 340H of the second sub-pixel PX2. A third semiconductor light-emitting element 150-3 having a shape corresponding to the shape of the assembly hole 340H can be assembled into the assembly hole 340H of the third sub-pixel PX3. Accordingly, since the first semiconductor light-emitting element 150-1, the second semiconductor light-emitting element 150-2, and the third semiconductor light-emitting element 150-3 having different shapes are assembled into the assembly hole 340H corresponding to their own shapes, respectively, assembly failure can be prevented.

Meanwhile, the plurality of semiconductor light-emitting elements may comprise a first semiconductor light-emitting element 150-1 that emits a first color light, a second semiconductor light-emitting element 150-2 that emits a second color light, and a third semiconductor light-emitting element 150-3 that emits a third color light. For example, at least one or more first semiconductor light-emitting element 150-1 may be disposed in a plurality of first sub-pixels PX1 arranged along the first direction, respectively. For example, at least one or more second semiconductor light-emitting element 150-2 may be disposed in a plurality of second sub-pixels PX2 arranged along the first direction, respectively. For example, at least one or more third semiconductor light-emitting element 150-3 may be disposed in a plurality of third sub-pixels PX3 arranged along the first direction, respectively.

Meanwhile, the connection electrode 370 may be disposed in the assembly hole 350H. For example, the connection electrode 370 may be disposed around the semiconductor light-emitting element 150-1, 150-2, and 150-3 within the assembly hole 370H.

The thickness of the connection electrode 370 may be smaller than the thickness of the partition wall 340, but is not limited thereto.

The connection electrode 370 may be connected to the first electrode 154 of the first semiconductor light-emitting element 150-1 of the first sub-pixel PX1. In addition, the connection electrode 370 may be disposed within the first recess 158 of the first semiconductor light-emitting element 150-1 of the first sub-pixel PX1. Accordingly, the contact area between the connection electrode 370 and the first semiconductor light-emitting element 150-1 may be expanded, so that the current flow can become smoother and the luminance can be improved.

Although not shown, the connection electrode 370 may also be connected to the second semiconductor light-emitting element 150-2 of the second sub-pixel PX2 or the third semiconductor light-emitting element 150-3 of the third sub-pixel PX3.

In addition, since the connection electrode 370 is disposed along the perimeter of the semiconductor light-emitting element 150-1, 150-2, and 150-3 within the assembly hole 340H, the partition wall 340 and the semiconductor light-emitting element 150-1, 150-2, and 150-3 may be firmly fixed by the connection electrode 370, so that the fixing strength can be strengthened.

In addition, when the side portion of the first semiconductor region 150-11 is connected to the first assembling wiring or the second assembling wiring through the connection electrode 370, the connection electrode 370 can be in contact not only with the side portion of the first semiconductor region 150-11 but also with the first recess 158. In particular, since the connection electrode 370 is formed also inside the first recess 158, the bonding force between the connection electrode 370 and the semiconductor light-emitting element 150C may be strengthened, so that the fixing property of the semiconductor light-emitting element 150C can be improved, thereby enhancing product reliability. At this time, the passivation layer 157 may be removed on the side portion of the first semiconductor region 150-11, so that the connection electrode 370 can be disposed in the first recess 158 and directly contact the upper surface of the first-first semiconductor layer 151-1, the side surface of the first-second semiconductor layer 151-2, and the lower surface of the first-third semiconductor layer 151-3.

Meanwhile, the second insulating layer 350 may be disposed on the partition wall 340 to protect the semiconductor light-emitting element 150-1. The second insulating layer 350 may be disposed in the assembly hole 340H around the semiconductor to firmly fix the semiconductor light-emitting element 150-1. In addition, the second insulating layer 350 may be disposed on the semiconductor light-emitting element 150-1 to protect the semiconductor light-emitting element 150-1 from external impact and prevent the semiconductor light-emitting element 150-1 from being contaminated by foreign substances.

The insulating layer 350 can serve as a planarization layer that enables a layer formed in a subsequent process to be formed with a constant thickness. Accordingly, the upper surface of the second insulating layer 350 can have a flat surface. The second insulating layer 350 can be formed of an organic material or an inorganic material. Accordingly, the electrode wiring 362 can be easily formed without a short circuit on the upper surface of the second insulating layer 350 having a flat surface.

A plurality of electrode wirings 362 can be disposed on the upper side of the plurality of semiconductor light-emitting elements 150-1, 150-2, and 150-3, respectively. Each of the first sub-pixel PX1, the second sub-pixel PX2, and the third sub-pixel PX3 can comprise the electrode wiring 362.

For example, the electrode wiring 362 can be disposed on the upper side of the first semiconductor light-emitting element 150-1 disposed in the first sub-pixel PX1. The electrode wiring 362 may be connected to the second side portion of the first semiconductor light-emitting element 150-1 through the contact hole 350H2. For example, the electrode wiring 362 may be disposed on the upper side of the second semiconductor light-emitting element 150-2 disposed in the second sub-pixel PX2. The electrode wiring 362 may be connected to the second side portion of the second semiconductor light-emitting element 150-2 through the contact hole 350H2. For example, the electrode wiring 362 may be disposed on the upper side of the third semiconductor light-emitting element 150-3 disposed in the third sub-pixel PX3. The electrode wiring 362 may be connected to the second side portion of the third semiconductor light-emitting element 150-3 through the contact hole 350H2.

The electrode wiring 362 may be disposed on the second insulating layer 350. For example, the electrode wiring 362 may be made of a transparent conductive material that allows light to pass through. For example, the electrode wiring 362 may comprise ITO, IZO, etc., but is not limited thereto.

Meanwhile, the first assembling wiring 321 and/or the second assembling wiring 322 may be used as the first electrode wiring, and the electrode wiring 362 may be the second electrode wiring 362. Accordingly, the first semiconductor substrate element may emit first color light, for example, red light, by a voltage applied between the first assembling wiring 321 and/or the second assembling wiring 322 and the electrode wiring 362.

Meanwhile, the display device 300 according to the embodiment may comprise a plurality of signal lines SL1, SL2, SL3, and SL4. The plurality of signals may comprise a first signal line SL1, a second signal line SL2, a third signal line SL3, and a fourth signal line SL4. The plurality of signal lines SL1, SL2, SL3, and SL4 may be disposed in the same layer.

The plurality of signal lines SL1, SL2, SL3, and SL4 may be disposed in a different layer from the second electrode wiring 362. Accordingly, the plurality of signal lines SL1, SL2, SL3, and SL4 and the second electrode wiring 362 may be electrically connected through the plurality of contact holes 351H1, 351H2, and 351H3. For example, the first signal line SL1 and the second electrode wiring 362 may be electrically connected through the first contact hole 351H1. For example, the second signal line SL2 and the second electrode wiring 362 may be electrically connected through the second contact hole 351H2. For example, the third signal line SL3 and the second electrode wiring 362 may be electrically connected through the third contact hole 351H3. For example, the fourth signal line SL4 and the first assembling wiring 321 and/or the second assembling wiring 322 may be electrically connected through the contact hole 352.

The plurality of signal lines SL1, SL2, SL3, and SL4 may be disposed in different layers from the first assembling wiring 321 and the second assembling wiring 322.

Meanwhile, the first signal line SL1 may be electrically connected to the plurality of first sub-pixels PX1. For example, the first signal line SL1 may be electrically connected to the second electrode 155 of the first semiconductor light-emitting element 150-1 through the second electrode wiring 362 of each of the plurality of first sub-pixels PX1.

The signal line SL2 may be electrically connected to the plurality of second sub-pixels PX2. For example, the second signal line SL2 may be electrically connected to the second electrode 155 of the second semiconductor light-emitting element 150-2 through the second electrode wiring 362 of each of the plurality of second sub-pixels PX2.

The signal line SL3 may be electrically connected to the plurality of third sub-pixels PX3. For example, the third signal line SL3 may be electrically connected to the second electrode 155 of the third semiconductor light-emitting element 150-3 through the second electrode wiring 362 of each of the plurality of third sub-pixels PX3.

The signal line SL4 may be commonly connected to the first sub-pixel PX1, the second sub-pixel PX2, and the third sub-pixel PX3. For example, the fourth signal line SL4 may be electrically connected to the first electrode 154 of the first semiconductor light-emitting element 150-1 via the first assembling wiring 321 and/or the second assembling wiring 322 of the first sub-pixel PX1. For example, the fourth signal line SL4 may be electrically connected to the first electrode 154 of the second semiconductor light-emitting element 150-2 via the first assembling wiring 321 and/or the second assembling wiring 322 of the second sub-pixel PX2. For example, the fourth signal line SL4 may be electrically connected to the first electrode 154 of the third semiconductor light-emitting element 150-3 via the first assembling wiring 321 and/or the second assembling wiring 322 of the third sub-pixel PX3.

For example, the first signal line SL1, the second signal line SL2, and the third signal line SL3 may each be supplied with a positive (+) voltage. For example, the fourth signal line SL4 may be grounded or supplied with a negative (−) voltage. The positive (+) voltages supplied to the first signal line SL1, the second signal line SL2, and the third signal line SL3 may be the same, but are not limited thereto.

For example, the first signal line SL1 connected to the first sub-pixel PX1 may be a high-potential voltage line VDDL as shown in FIG. 7. For example, the second signal line SL2 connected to the second sub-pixel PX2 and the third signal line SL3 connected to the third sub-pixel PX3 may also be high-potential signal lines VDDL to which a high-potential voltage (VDD of FIG. 6) may be supplied. For example, the fourth signal line SL4 commonly connected to each of the first sub-pixel PX1, the second sub-pixel PX2, and the third sub-pixel PX3 may be a low-potential signal line VSSL to which a low-potential voltage (VSS of FIG. 6) may be supplied.

Although not shown in the drawing, a driving transistor (DT of FIG. 7) may be provided between the first signal line SL1 and the first semiconductor light-emitting element 150-1 of the first sub-pixel PX1, the second signal line SL2 and the second semiconductor light-emitting element 150-2 of the second sub-pixel PX2, and the third signal line SL3 and the third semiconductor light-emitting element 150-3 of the third sub-pixel PX3. At this time, the gate terminal of the driving transistor DT may be connected to the data line Dj via the scan transistor ST.

Therefore, the first sub-pixel PX1, the second sub-pixel PX2, and the third sub-pixel PX3 may each be provided with a scan transistor ST, a driving transistor DT, and a semiconductor light-emitting element 150-1, 150-2, and 150-3. At this time, the driving transistor DT may be connected to the scan transistor ST and the semiconductor light-emitting element 150-1, 150-2, and 150-3, and the scan transistor ST may be connected to the data line Dj. The driving transistors ST of the first sub-pixel PX1, the second sub-pixel PX2, and the third sub-pixel PX3 may be connected to the high-potential signal line VDDL, that is, the first to third signal lines SL1, SL2, and SL3, respectively. The semiconductor light-emitting elements 150-1, 150-2, and 150-3 of the first sub-pixel PX1, the second sub-pixel PX2, and the third sub-pixel PX3 may be connected to the low-voltage signal line VSSL, i.e., the fourth signal line SL4, respectively.

Depending on the data voltage supplied to the data line Dj, the current flowing through the driving transistor ST becomes different, and due to the different currents, the light intensity, i.e., the luminance or gradation, of the semiconductor light-emitting elements 150-1, 150-2, and 150-3 of the first sub-pixel PX1, the second sub-pixel PX2, and the third sub-pixel PX3 becomes different, so that images having different brightness may be displayed.

Meanwhile, the display device described above may be a display panel. That is, in the embodiment, the display device and the display panel may be understood to have the same meaning. In an embodiment, the display device in a practical meaning may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment can be adopted in the display field for displaying images or information. The embodiment can be adopted in the display field for displaying images or information using a semiconductor light-emitting element. The semiconductor light-emitting element can be a micro-level semiconductor light-emitting element or a nano-level semiconductor light-emitting element.

For example, the embodiment can be adopted in a TV, a signage, a smart phone, a mobile phone, a mobile terminal, a HUD for an automobile, a backlight unit for a notebook, and a display device for VR or AR.

1. A semiconductor light-emitting element, comprising:
a first semiconductor region having a first shape; and
a second semiconductor region having a second shape different from the first shape on the first semiconductor region; and
at least one or more second recess along an outer peripheral surface of the second semiconductor region, and
wherein the second recess is a texture having a bottom surface, an inner surface, and a top surface,
wherein the second semiconductor region has a first side portion, a second side portion, a third side portion facing the first side portion, and a fourth side portion facing the second side portion,
wherein a distance between the first side portion and the third side portion is smaller than a diameter of the circular shape, and
wherein a distance between the second side portion and the fourth side portion is smaller than a diameter of the circular shape.

2. The semiconductor light-emitting element of claim 1, wherein the first shape has a circular shape, and the second shape has a rectangular shape.

3. (canceled)

4. The semiconductor light-emitting element of claim 2,
wherein the second recess comprises:
a second-first recess having a first angle on the first side portion;
a second-second recess having a second angle on the second side portion;
a second-third recess having a third angle on the third side portion; and
a second-fourth recess having a fourth angle on the fourth side portion, and
wherein the first angle, the second angle, the third angle, and the fourth angle are angles of the inner surface with respect to the bottom surface, respectively.

5. The semiconductor light-emitting element of claim 4, wherein the second-first recess, the second-second recess, the second-third recess, and the second-fourth recess are configured to be connected to each other along the outer peripheral surface of the second semiconductor region.

6. The semiconductor light-emitting element of claim 4, wherein the first angle and the third angle are the same, and the second angle and the fourth angle are the same.

7. The semiconductor light-emitting element of claim 6, wherein the first angle and the third angle are each an acute angle, and the second angle and the fourth angle are each an obtuse angle.

8. The semiconductor light-emitting element of claim 4, wherein the first angle, the second angle, the third angle, and the fourth angle are the same.

9. The semiconductor light-emitting element of claim 1, further comprising:
at least one or more first recess along an outer peripheral surface of the first semiconductor region.

10. The semiconductor light-emitting element of claim 9, wherein an angle of the first recess is variable along the outer peripheral surface, and the angle is an angle of the inner surface with respect to the bottom surface.

11. The semiconductor light-emitting element of claim 10, wherein an variable range of the angle is from 60 degrees to 120 degrees.

12. The semiconductor light-emitting element of claim 9, wherein the first recess has a circular ring, the second recess has a rectangular ring, and the rectangular ring is positioned within the circular ring.

13. The semiconductor light-emitting element of claim 9, wherein the first semiconductor region comprises:
a plurality of first semiconductor layers, and
wherein the second semiconductor region comprises:
an active layer on the plurality of first semiconductor layers; and
a plurality of second semiconductor layers on the active layer.

14. The semiconductor light-emitting element of claim 13, wherein the first recess is positioned below the active layer, and the second recess is positioned above the active portion.

15. The semiconductor light-emitting element of claim 13, wherein the plurality of first semiconductor layers comprises:
a first-first semiconductor layer comprising a first dopant;
a first-second semiconductor layer comprising the first dopant on the first-first semiconductor layer; and
a first-third semiconductor layer on the first-second semiconductor layer, and
wherein the first recess is disposed along an outer peripheral surface of the first-second semiconductor layer, and
wherein a side portion of the first-second semiconductor layer is closer to a center of the first semiconductor region than a side portion of the first-first semiconductor layer and a side portion of the first-third semiconductor layer.

16. The semiconductor light-emitting element of claim 14, wherein the plurality of second semiconductor layers comprise:
a second-first semiconductor layer;
a second-second semiconductor layer comprising a second dopant on the second-first semiconductor layer; and
a second-third semiconductor layer comprising the second dopant on the second-second semiconductor layer, and
wherein the second recess is disposed along an outer peripheral surface of the second-second semiconductor layer, and
wherein a side portion of the second-second semiconductor layer is closer to a center of the second semiconductor region than a side portion of the second-first semiconductor layer and a side portion of the second-third semiconductor layer.

17. A display device, comprising:
a substrate comprising a plurality of sub-pixels;
a plurality of first assembling wirings in the plurality of sub-pixels, respectively;
a plurality of second assembling wirings in the plurality of sub-pixels, respectively;
a partition wall having a plurality of assembly holes in the plurality of sub-pixels, respectively;
a plurality of semiconductor light-emitting elements in the plurality of assembly holes, respectively; and
a connection electrode surrounding a side portion of each of the plurality of semiconductor light-emitting elements;
an electrode wiring on an upper side of each of the plurality of semiconductor light-emitting elements, and
wherein each of the plurality of semiconductor light-emitting elements comprises:
a first semiconductor region having a first shape;
a second semiconductor region having a second shape different from the first shape on the first semiconductor region; and
at least one or more second recess along an outer peripheral surface of the second semiconductor region, and,
wherein the second recess is a texture having a bottom surface, an inner surface, and a top surface,
wherein the second semiconductor region has a first side portion, a second side portion, a third side portion facing the first side portion, and a fourth side portion facing the second side portion,
wherein a distance between the first side portion and the third side portion is smaller than a diameter of the circular shape, and
wherein a distance between the second side portion and the fourth side portion is smaller than a diameter of the circular shape.

18. The display device of claim 17, wherein the connection electrode is configured to connect at least one of the first assembling wiring or the second assembling wiring to a side portion of the first semiconductor region.

19. The display device of claim 18, wherein each of the plurality of semiconductor light-emitting elements comprises:
at least one or more first recess along an outer peripheral surface of the first semiconductor region, and
wherein the connection electrode is disposed in the at least one or more first recess.
